(19) United States
(12) Patent Application Publication
(10) Pub. No.: US 2009/0109069 A1
(43) Pub. Date: Apr. 30, 2009

(54) INPUT DEVICE AND MOBILE TERMINAL USING THE SAME

(76) Inventors: Shinichi Takasaki, Osaka (JP); Shigeyuki Inoue, Kyoto (JP); Hiroshi Yamamoto, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/295,176

(22) PCT Filed: Mar. 22, 2007
(86) PCT No.: PCT/JP2007/055801

§ 371 Date: Sep. 29, 2008

(30) Foreign Application Priority Data
Apr. 7, 2006 (JP) 2006-106819
Apr. 7, 2006 (JP) 2006-106824
Jul. 11, 2006 (JP) 2006-190512

(51) Int. Cl. H03K 17/94

(52) U.S. Cl. 341/35

(57) ABSTRACT

The present invention provides an input device (2) in which a user can efficiently find target information.

The input device (2) includes: an operation unit (8) which is operated by the user; a movement sensing unit which senses a physical amount related to a movement of an object in contact with a surface of the operation unit (8), or a physical amount related to a movement of the operation unit (8); a pressing sensing unit which senses that the surface of the operation unit (8) is pressed; an information set storage unit which stores a plurality of information sets constituting a hierarchical structure with at least three layers; a selection unit which selects unit information from among the information sets, depending on the physical amount; and a confirmation unit which, when it is sensed that the operation unit (8) is pressed or that the pressing on the operation unit (8) is released, confirms the selection of the unit information, wherein when selection of unit information in an information set of an n-th layer is confirmed, the selection unit shifts to a state in which unit information is selected from among an information set of an m-th layer between a highest layer and the n-th layer.

### TECHNICAL FIELD

The present invention relates to an input device which inputs information, and further relates to a mobile terminal including the input device, such as a mobile phone or a PDA.

### BACKGROUND ART

FIG. 1 is an external view of a conventional mobile terminal 100. As shown in FIG. 1, the conventional mobile terminal 100 has functions which realize telephone calls, transmission and receiving of mails, Internet connections, and the like, and includes an integrated operation unit 101 as an input device, and in addition, includes a display unit 102, a speech output unit 103, a speech input unit 104, and the like. On the operation unit 101 of the mobile terminal 100, input keys, function keys, a selection key, and a determination key are arranged. The input keys are 12 kinds of keys composed of number keys of 0 to 9, a * key, and a # key, and these keys are used to input character-related information such as hiragana, katakana, alphabet, numbers, and signs. The function keys are associated with function information such as “mail”, “Web browsing”, “camera”, “clear”, “memo”, and “manner”, and are keys which are used when these functions are used. The selection key and the determination key are keys which are used when a user selects and determines target information from among plural pieces of the character-related information or the function information.

In the above described conventional mobile terminal 100, it is possible to communicate with another user by using a mail function and the like, and therefore, an occasion of inputting the character-related information frequently occurs. Thus, numerous pieces of the character-related information such as the numbers, the hiragana, the katakana, and the alphabet have been assigned to the 12 kinds of the input keys. In other words, to the respective keys assigned with the numbers 0 to 9 in the input keys, 10 kinds of information grouped for each line ( [symbol] (a)-line to [symbol] (wa)-line) in a 50-character hiragana syllabary, and 10 kinds of information grouped for each line ( [symbol] (a)-line to [symbol] (wa)-line) in a 50-character katakana syllabary have been assigned, and in addition, A to Z of the alphabet have been grouped into 10 pieces and assigned. Furthermore, also to other keys assigned with two kinds of signs (* and #), the signs including a punctuation, a voiced sound mark, a semi-voiced sound mark, and the like, have been generally grouped and assigned.

In this way, since the plural pieces of the character-related information have been assigned to one input key, it is necessary for the user to press the same key, a plural number of times, to change a character to be inputted. For example, when a character “ [symbol] (O)” is desired to be inputted, it is necessary to press a key assigned with [symbol] (a)-line, a plural number of times, to change display in an order of “ [symbol] (a)”→“ [symbol] (i)”→“ [symbol] (u)”→“ [symbol] (e)”→“ [symbol] (o)”. Moreover, since a plurality of character-related information sets have been assigned to one input key, it is necessary for the user to press a predetermined function key to switch the character-related information sets. For example, when a number is desired to be inputted while the hiragana is being inputted, it is necessary to press a character switching key to switch from hiragana input to number input.

When the character-related information is inputted with such a combination of the input keys and the function keys, the selection key, the determination key, and the like, a method in which the user holds the mobile terminal in one hand while seeing the display unit and performs a operation with his thumb of this one hand is common. However, it cannot necessarily be said that the conventional mobile terminal 100 as described above has a configuration in which the user can easily perform an input operation. For example, when the user uses the mobile terminal 100 to input characters of “ [symbol] (o) [symbol] (ha) [symbol] (yo) [symbol] (u)”, in order to input “ [symbol] (o)”, it is necessary to press a number 1 key five times to change the display in the order of “ [symbol] (a)”→“ [symbol] (i)”→“ [symbol] (u)”→“ [symbol] (e)”→“ [symbol] (o)”. Next, in order to input “ [symbol] (ha)”, it is necessary to press a number 6 key once to display “ [symbol] (ha)”. Subsequently, in order to input “ [symbol] (yo)”, it is necessary to press a number 8 key three times to change the display in an order of “ [symbol] (ya)”→“ [symbol] (yu)”→“ [symbol] (yo)”. Finally, in order to input “ [symbol] (u)”, it is necessary to press the number 1 key three times to change the display in an order of “ [symbol] (a)”→“ [symbol] (i)”→“ [symbol] (u)”. In other words, in order to input four characters of “ [symbol] (o) [symbol] (ha) [symbol] (yo) [symbol] (u)”, it becomes necessary to press the keys 10 times in total. At this time, the user has to take his eyes from the display unit and check the operation unit in order to find target keys (in the above described case, the number 1 key, the number 6 key, and the number 8 key) from the 12 kinds of the input keys. Moreover, when the input is performed with a combination of different character-related information sets such as the hiragana, the katakana, and the numbers, it is necessary to use the function key such as the character switching key to switch the character-related information sets, and therefore, the user's burden of checking the operation unit increases. Furthermore, since the character-related information has been grouped and assigned to a plurality of the input keys, the user has to perform the input operation by moving a finger (mainly, the thumb) which performs the operation, to a key assigned with target character-related information.

As above, in the conventional mobile terminal 100, since the plurality of character-related information sets which have been grouped, have assigned to the plurality of input keys, the user has to move the thumb among the plurality of input keys to input the character-related information, and each time, the user has to take his eyes from the display unit and see the operation unit to visually recognize a target input key. Moreover, when the user has taken his eyes from the display unit once and operated the input key while seeing the operation unit, the user has to see the display unit again to check whether or not the target character-related information has been inputted without mistakes. In this case, when the plural pieces of the character-related information have been displayed on the display unit, the target character-related information has to be found from among the plural pieces of the character-related information.

Thus, the more the character-related information is inputted, the more a time for seeing the operation unit and the display unit to find target characters, and checking whether or not the character-related information has been correctly inputted is required, and therefore, an input speed is lowered. Moreover, the movement of the finger among the input keys increases a burden on the hand or the finger which performs the operation. Thus, when the conventional mobile terminal 100 is used to attempt to input much character-related information, the attempt may cause mental and physical fatigue. In addition, when the fatigue has been accumulated on the hand or the finger which performs the operation, the mobile terminal may be dropped and broken while being re-held, or the like.

This problem has remarkably appeared due to increase in the number of times of key operations in accordance with more multifunctional mobile terminals in recent years. Particularly, in a character input operation for the mails and the like, in accordance with increase in the number of characters in the mail which can be transmitted, the number of times of key operations has significantly increased, which is thus likely to cause the mental and physical fatigue, and has been a problem which should be immediately solved. Consequently, as described below, an input device which reduces the burden on the user has been proposed (for example, refer to Patent Reference 1).

FIG. 2 is a diagram showing a media player 400 disclosed in Patent Reference 1. As shown in this FIG. 2, in order to select a target song (item) from among a song list 422 which is displayed on a display screen 404, a user 420 scrolls the song list 422 in a direction of an arrow 424 via a slider bar 423. The media player 400 is comfortably fitted in one hand 426, while being comfortably operated by the other hand 428. As shown by an arrow 434, a rotary input device 410 is continuously driven by a circular movement of a finger 432. For example, when a rotary motion of 360 degrees is performed in a direction of the arrow 434 without stopping the finger 432, the song list 422 which is displayed on a display screen 404 is continuously scrolled. In such a media player, items are managed with a menu (list) having a hierarchical structure (for example, refer to Patent Reference 2).

FIG. 3 is a diagram showing a menu 200 disclosed in Patent Reference 2. As shown in this FIG. 3, when a specific music genre 202 is selected in a highest genre layer, there is a transition to an artist layer for selecting an artist 204 in that genre 202. When a specific artist 204 is selected in this artist layer, there is a transition to an album layer for selecting an album 206 related to that artist 204. When a specific album 206 is selected in this album layer, there is a transition to a song layer for selecting a song 208 belonging to that album 206. When a specific song 208 is selected in this song layer, that song 208 is played, and when the play is completed, the song layer to which that song 208 belongs stays there. When the user hopes to continuously play a song 208 belonging to the same album, it is possible to select a target song 208 from among songs 208 belonging to the above described song layer.

According to the media player as described above, it is possible to select a target item only by operating a single device which is the rotary input device 410. According to such an operation method, since only a small number of times of pressing the keys are required and also it is possible to select the target item by seeing only the display unit without seeing the operation unit, it is possible to reduce the burden on the user. In addition, even with such a simple operation method, since many items are presented to the user with the menu having the hierarchical structure, convenience for the user is not impaired.

Patent Reference 1: U.S. Patent Application Publication No. 2003/0095096 specification (FIGS. 3, 5)
Patent Reference 2: U.S. Patent Application Publication No. 2004/0055446 specification (FIGS. 2, 4)

### DISCLOSURE OF INVENTION

### Problems that Invention is to Solve

However, according to the media player disclosed in the above-described Patent Reference 2, when play of one song is completed, a song layer to which that song belongs stays there, and therefore, for example, after the play of one song has been completed, when a song belonging to an album different from that song is desired to be played, an operational efficiency is reduced. In other words, in such a case, the selection has to be newly redone from the highest layer, or an operation (pressing a “Return” button, or the like) other than a selection operation has to be performed.

The present invention aims at solving the above described problem, and it is an object of the present invention to provide an input device in which the user can efficiently find the target information even when a large amount of information is managed with the menu having the hierarchical structure.

### Means to Solve the Problems

In order to achieve the aforementioned object, the input device according to the present invention is an input device which inputs information, the device includes: an operation unit which is operated by a user; a movement sensing unit which senses a physical amount related to a movement of an object in contact with a surface of the operation unit, or a physical amount related to a movement of the operation unit; a pressing sensing unit which senses that the surface of the operation unit is pressed; an information set storage unit which stores a plurality of information sets constituting a hierarchical structure with at least three layers; a selection unit which selects unit information from among the information sets, depending on the physical amount which is sensed by the movement sensing unit; and a confirmation unit which confirms the selection of the unit information, when it is sensed by the pressing sensing unit that the operation unit is pressed or that the pressing on the operation unit is released, wherein when the selection of unit information in an information set of an n-th layer is confirmed by the confirmation unit, the selection unit shifts to a state in which unit information is selected from among an information set of an m-th layer between a highest layer and the n-th layer. Therefore, after input of one character has been completed, when a character is desired to be successively inputted, it is not necessary to perform an operation for a transition in a hierarchy. In other words, even when a large amount of information is managed with a menu having a hierarchical structure, it becomes possible for the user to efficiently find target information.

Here, the information set belonging to the m-th layer may be a collection of line information corresponding to each character constituting a beginning line of a 50-character hiragana syllabary, and the information set belonging to the n-th layer may be a collection of column information corresponding to each character belonging to each line of the 50-character hiragana syllabary. Thereby, in the case where hiragana is inputted, it becomes possible to, when selection of a line character is confirmed, shift to a state in which a column character belonging to that line is selected, and when the selection of the column character is confirmed, shift to a state in which the line character is selected.

Furthermore, the information set belonging to the m-th layer may be a collection of unit information indicating an artist, and the information set belonging to the n-th layer may be a collection of unit information indicating a tune belonging to the artist. Thereby, in the case where a music function is selected and the tune is played, it becomes possible to, when selection of the artist is confirmed, shift to a state in which the tune belonging to that artist is selected, and when the selection of the tune is confirmed, shift to a state in which the artist is selected.

Furthermore, the information set belonging to the m-th layer may be a collection of unit information indicating a music album, and the information set belonging to the n-th layer may be a collection of unit information indicating a tune belonging to the music album. Thereby, in the case where the music function is selected and the tune is played, it becomes possible to, when selection of the music album is confirmed, shift to a state in which the tune belonging to that music album is selected, and when the selection of the tune is confirmed, shift to a state in which the music album is selected. Furthermore, the information set belonging to the m-th layer may be a collection of unit information indicating a music genre, and the information set belonging to the n-th layer may be a collection of unit information indicating a tune constituting the music genre. Thereby, in the case where the music function is selected and the tune is played, it becomes possible to, when selection of the music genre is confirmed, shift to a state in which the tune constituting that music genre is selected, and when the selection of the tune is confirmed, shift to a state in which the music genre is selected.

Furthermore the information set belonging to the m-th layer may be a collection of unit information indicating a music playlist, and the information set belonging to the n-th layer may be a collection of unit information indicating a tune belonging to the music playlist. Thereby, in the case where the music function is selected and the tune is played, it becomes possible to, when selection of the music playlist is confirmed, shift to a state in which the tune belonging to that music playlist is selected, and when the selection of the tune is confirmed, shift to a state in which the music playlist is selected.

Furthermore, the information set belonging to the m-th layer is a collection of unit information indicating a television program genre, and the information set belonging to the n-th layer is a collection of unit information indicating a television program belonging to the television program genre. Thereby, in the case where a television function is selected and the television program is played, it becomes possible to, when selection of the television program genre is confirmed, shift to a state in which the television program constituting that genre is selected, and when the selection of the television program is confirmed, shift to a state in which the television program genre is selected.

Furthermore, the information set storage unit may store a first information set which is a collection of first unit information, and a second information set which is a collection of second unit information associated with the first unit information, and when the second unit information is confirmed as input information by the confirmation unit, the selection unit may return to selection of the first unit information from the first information set. Thereby, for example, in the case where the hiragana is inputted, when selection of predetermined first unit information (for example, “ [symbol] (a)” line) from among line information (“ [symbol] (a)” line, “ [symbol] (ka)” line, “ [symbol] (sa)” line, “ [symbol] (ta)” line, “ [symbol] (na)” line, and the like) which is the first information set is confirmed, the state shifts to a state in which column information (“ [symbol] (a)”, “ [symbol] (i)”, “ [symbol] (u)”, “ [symbol] (e)”, and “ [symbol] (o)”, for “ [symbol] (a)” line) which is the second information set belonging to that line is selected, and when selection of predetermined second unit information (for example, “ [symbol] (u)”) from among the column information is confirmed, the state shifts to a state in which the line information which is the first information set is selected. Therefore, after the input of one character has been completed, when a character is desired to be successively inputted, it is not necessary to perform the operation for the transition in the hierarchy. In other words, it becomes possible for the user to efficiently input a target character.

Furthermore, the selection unit may start the selection of the first unit information, with the first unit information associated with the second information set, as a reference point. Thereby, when the user confirms selection of one character (for example, “ [symbol] (mi)”), and subsequently, successively performs the selection of the line information which is the first information set, the selection unit does not start the selection from the same line character (for example, “ [symbol] (a)” line) every time one character is inputted, and selects the first unit information (“ [symbol] (ma)” line) which has been associated with the second information set to which the confirmed second unit information (“ [symbol] (mi)”) belongs. Therefore, since a time for the selection of the line information is reduced, a burden on the user's hand or finger is reduced, and moreover, it becomes possible to reduce a time required for an operation.

Furthermore, the input device may include an information presentation unit which presents, on a screen, selected target information selected by the selection unit, the selected target information including at least a portion of the information sets, wherein, when the second unit information is confirmed as the input information by the confirmation unit, the information presentation unit may present, on the screen, an information set including the first unit information associated with the second information set, as the selected target information. Thereby, since the information being selected by the user is presented by the information presentation unit, it becomes unnecessary for the user to visually recognize a key assigned with the target information when performing an input operation. Thus, a time required for the input operation can be reduced.

Furthermore, when presenting the first unit information as the selected target information, the information presentation unit may present the first unit information in an external appearance different from other unit information in the selected target information. Thereby, since the character being selected by the user is presented in an external appearance different from characters previous and next thereto, it becomes easier to comprehend the character to be inputted, and it becomes possible to further reduce the time required for the operation.

Furthermore, the information presentation unit may include an information presentation unit which presents the first unit information selected by the selection unit, in a display size larger than selected target unit information other than the first unit information. Thereby, since the character being selected by the user is presented in a display size larger than the characters previous and next thereto, it becomes easier to comprehend the character to be inputted, and it becomes possible to further reduce the time required for the operation.

Furthermore, the input device may further include the information presentation unit which presents the selected target information which includes at least some of the information sets and is selected by the selection unit, on the screen; and an information presentation unit which presents a predetermined piece of the first unit information selected by the selection unit, in a color different from the selected target information other than the first unit information. Thereby, since the character being selected by the user is presented in a color different from the characters previous and next thereto, it becomes easier to comprehend the character to be inputted, and it becomes possible to further reduce the time required for the operation.

Furthermore, the input device may include a history information retention unit which stores history information related to unit information confirmed in the past, as input information, by the confirmation unit, wherein the selection unit may select the unit information which becomes a reference point, based on the history information. Thereby, when the user uses, for example, a mail function to input the character, the selection is not started from the same character (for example, “ [symbol] (a)”) every time, and it is possible to determine a character to be selected first, based on a character of which selection has been confirmed when the user has used the mail function in past times. Thus, since a time for selection of the first character is reduced when a predetermined function has been used, the burden on the user's hand or finger is reduced, and moreover, it becomes possible to reduce the time required for the operation.

Furthermore, the operation unit may be a rotary body provided on a base body of the input device, the movement sensing unit may be an amount of rotation sensing unit which senses an amount of rotation of the rotary body, the selection unit may include: a first selection unit which selects information from among the information sets, depending on the amount of rotation from a position of the rotary body when the rotary body is pressed and immediately preceding input information is confirmed, with first reference unit information in the information sets as a reference point; and a second selection unit which selects unit information from among the information sets, depending on the amount of rotation from a reference position of the rotary body, with second reference unit information in the information sets as the reference point, and the input device may further include a switching unit which switches between the first selection unit and the second selection unit. Thereby, it is possible to switch between the first selection unit (hereinafter also referred to as “relative input method”) in which the information being selected by the user can be known only from a display unit, and the second selection unit (hereinafter also referred to as “absolute input method”) in which the information being selected by the user is displayed on the display unit and also can be comprehended from a position of the operation unit with respect to the input device. In other words, it becomes possible to switch between an input method suitable for inputting the information while seeing only the display unit, and an input method suitable for inputting the information while seeing both the display unit and the operation unit.

Furthermore, the input device may further include a reference position setting unit which changes the amount of rotation to 0 when the switching from the first selection unit to the second selection unit is performed by the switching unit, and thereby set, as the reference position, a position of the rotary body at a time point when the switching is performed. Thereby, when switching from the above described first selection unit to the above described second selection unit is performed while the position of the above described operation unit is at a predetermined position, it becomes possible to set the position of the above described operation unit when a predetermined character is inputted, to be always constant.

Furthermore, when it is sensed by the pressing sensing unit that a duration in which the rotary body is pressed is equal to or more than a predetermined threshold, the switching unit may switch between the first selection unit and the second selection unit. Thereby, it becomes possible to switch between the above described first selection unit and the above described second selection unit by performing a simple operation of long-pressing the above described rotary body.

Furthermore, when it is sensed by the pressing sensing unit that the number of times that the rotary body is successively pressed is equal to or more than a predetermined threshold, the switching unit may switch between the first selection unit and the second selection unit. Thereby, it becomes possible to switch between the above described first selection unit and the above described second selection unit by performing a simple operation of successively pressing the above described rotary body, equal to or more than a predetermined number of times.

Furthermore, the pressing sensing unit may sense whether or not there is pressing on a predetermined button; and when it is sensed by the pressing sensing unit that a duration for which the predetermined button is pressed is equal to or more than a predetermined threshold, the switching unit may switch between the first selection unit and the second selection unit. Thereby, it becomes possible to switch between the above described first selection unit and the above described second selection unit by performing a simple operation of long-pressing the predetermined button.

Furthermore, when it is sensed by the pressing sensing unit that the number of times the predetermined button is successively pressed is equal to or more than a predetermined threshold, the switching unit may switch between the first selection unit and the second selection unit. Thereby, it becomes possible to switch between the above described first selection unit and the above described second selection unit by performing a simple operation of successively pressing the predetermined button, a predetermined number of times.

Furthermore, the input device may further include a switch, wherein, when the switch is switched, the switching unit may switch between the first selection unit and the second selection unit. Thereby, it becomes possible to switch between the above described first selection unit and the above described second selection unit by performing a simple operation of switching a predetermined switch.

Furthermore, the input device may further include an information presentation unit which presents, at a periphery of the rotary body, an information set including information which is selected by the second selection unit. Thereby, since a predetermined information set is presented around the above described rotary body, it becomes further possible to set an input method suitable for inputting the information without seeing the display unit.

Furthermore, when the second reference unit information is a number “0” and the rotary body is at the reference position, the second selection unit may select “0” as input information. Thereby, when the above described operation unit is at the above described reference position, the number “0” is selected, and it becomes possible to improve usability.

Furthermore, when the second reference unit information is “a” of alphabet and the rotary body is at the reference position, the second selection unit may select “a” of the alphabet as input information. Thereby, when the above described operation unit is at the above described reference position, “a” of the alphabet is selected, and it becomes possible to improve the usability.

Note that it is possible to embody the present invention not only as such an input device, but also as: a mobile terminal including such an input device; an input method which includes, as their respective steps, characteristic units included in such an input device; and a program causing a computer to execute such steps. It should be also noted that, of course, such a program can be distributed on a recording medium such as a CD-ROM and over a transmission medium such as the Internet.

### EFFECTS OF THE INVENTION

As above, according to the input device according to the present invention, even when the large amount of information is managed with the menu having the hierarchical structure, it becomes possible for the user to efficiently find the target information.

For example, in the case where the hiragana is inputted, when the selection of the line character is confirmed, the state shifts to a state in which the column character belonging to that line is selected, and when the selection of the column character is confirmed, the state shifts to a state in which the line character is selected. Therefore, after the input of one character has been completed, when a character is desired to be successively inputted, it is not necessary to perform the operation for the transition in the hierarchy.

Alternatively, in the case where the music function is selected and the tune is played, when the selection of the album is confirmed, the state shifts to a state in which the tune belonging to that album is selected, and when the selection of the tune is confirmed, the state shifts to a state in which the album is selected. Therefore, after play of one song has been completed, when a song belonging to an album different from that song is desired to be played, it is not necessary to perform the operation for the transition in the hierarchy.

As a result, it is possible to reduce the burden on the user's hand or finger and reduce the time required for the operation, and it becomes possible to provide an input device and the like which can be comfortably operated by the user.

### BRIEF DESCRIPTION OF DRAWINGS

FIG. 1 is an external view of a conventional mobile terminal.

FIG. 2 is a diagram showing a media player disclosed in Patent Reference 1.

FIG. 3 is a diagram showing a menu disclosed in Patent Reference 2.

FIG. 4 is an external view of a mobile terminal including an input device in a first embodiment of the present invention.

FIG. 5 is a diagram showing a relationship between an operation unit and a cover of the mobile terminal in the first embodiment of the present invention.

FIG. 6A is a functional block diagram of an input unit in the first embodiment of the present invention.

FIG. 6B is a functional block diagram of the input unit in the first embodiment of the present invention.

FIG. 6C is a functional block diagram of the input unit in the first embodiment of the present invention.

FIG. 7 is an explanatory diagram of a contact sensing unit and a pressing sensing unit in the first embodiment of the present invention.

FIG. 8 is an example of character information stored in a storage unit in the first embodiment of the present invention.

FIG. 9 is a diagram conceptually representing a condition in which information sets have been hierarchically stored in the storage unit in the first embodiment of the present invention.

FIG. 10 is a flowchart showing a procedure when a character is inputted by using the mobile terminal in the first embodiment of the present invention.

FIG. 11A is a diagram showing an example of information which is displayed on a display unit when an input operation is being performed by using the mobile terminal in the first embodiment of the present invention.

FIG. 11B is a diagram showing an example of the information which is displayed on the display unit when the input operation is being performed by using the mobile terminal in the first embodiment of the present invention.

FIG. 11C is a diagram showing an example of the information which is displayed on the display unit when the input operation is being performed by using the mobile terminal in the first embodiment of the present invention.

FIG. 11D is a diagram showing an example of the information which is displayed on the display unit when the input operation is being performed by using the mobile terminal in the first embodiment of the present invention.

FIG. 11E is a diagram showing an example of the information which is displayed on the display unit when the input operation is being performed by using the mobile terminal in the first embodiment of the present invention.

FIG. 11F is a diagram showing an example of the information which is displayed on the display unit when the input operation is being performed by using the mobile terminal in the first embodiment of the present invention.

FIG. 12 is an external view of the mobile terminal including the input device in a second embodiment of the present invention.

FIG. 13 is a diagram representing a relationship between positions of a user's finger and an area with a heavy operational burden.

FIG. 14A is a diagram showing an example of the information which is displayed on the display unit when the input operation is being performed by using the mobile terminal in the second embodiment of the present invention.

FIG. 14B is a diagram showing an example of the information which is displayed on the display unit when the input operation is being performed by using the mobile terminal in the second embodiment of the present invention.

FIG. 14C is a diagram showing an example of the information which is displayed on the display unit when the input operation is being performed by using the mobile terminal in the second embodiment of the present invention.

FIG. 14D is a diagram showing an example of the information which is displayed on the display unit when the input operation is being performed by using the mobile terminal in the second embodiment of the present invention.

FIG. 14E is a diagram showing an example of the information which is displayed on the display unit when the input operation is being performed by using the mobile terminal in the second embodiment of the present invention.

FIG. 14F is a diagram showing an example of the information which is displayed on the display unit when the input operation is being performed by using the mobile terminal in the second embodiment of the present invention.

FIG. 15 is a diagram conceptually representing a condition in which the information sets have been hierarchically stored in the storage unit in the second embodiment of the present invention.

FIG. 16A is an example of the information which is displayed on the display unit when the input operation is being performed by using the mobile terminal in the second embodiment of the present invention.

FIG. 16B is an example of the information which is displayed on the display unit when the input operation is being performed by using the mobile terminal in the second embodiment of the present invention.

FIG. 16C is an example of the information which is displayed on the display unit when the input operation is being performed by using the mobile terminal in the second embodiment of the present invention.

FIG. 16D is an example of the information which is displayed on the display unit when the input operation is being performed by using the mobile terminal in the second embodiment of the present invention.

FIG. 16E is an example of the information which is displayed on the display unit when the input operation is being performed by using the mobile terminal in the second embodiment of the present invention.

FIG. 16F is an example of the information which is displayed on the display unit when the input operation is being performed by using the mobile terminal in the second embodiment of the present invention.

FIG. 17 is a diagram showing hierarchical association of other information sets.

FIG. 18 is a diagram showing hierarchical association of other information sets.

FIG. 19 is a diagram showing hierarchical association of other information sets.

FIG. 20 is a diagram showing hierarchical association of other information sets.

FIG. 21 is an external view of the mobile terminal including the input device in the second embodiment according to the present invention.

FIG. 22A is a configuration of a wheel unit constituting the input device in the second embodiment according to the present invention.

FIG. 22B is a diagram schematically representing signals outputted by a rotary encoder constituting the wheel unit.

FIG. 23A is a cross-sectional diagram showing a structure of the input device in the second embodiment according to the present invention.

FIG. 23B is a cross-sectional diagram showing the structure of the input device in the second embodiment according to the present invention.

FIG. 24 is a diagram representing a condition in which, when the input device of the present invention has been applied to a remote controller of a television, the user is using the remote controller and performing a character input operation.

FIG. 25 is a diagram showing terminals included in the input device in a third embodiment according to the present invention.

FIG. 26 is a block diagram showing a functional configuration of the input device in the third embodiment according to the present invention.

FIG. 27 is a diagram showing an example of the character information included in the storage unit included in the input device in the third embodiment according to the present invention.

FIG. 28 is a flowchart showing a procedure when a character is inputted according to a relative position input method by using the mobile terminal including the input device in the third embodiment according to the present invention.

FIG. 29A is a diagram showing a procedure when switching from the relative position input method to an absolute position input method is performed by using the mobile terminal including the input device in the third embodiment according to the present invention.

FIG. 29B is a diagram showing a correspondence between character-related information stored in the storage unit and sections.

FIG. 30 is a flowchart showing a procedure for inputting a character according to the absolute position input method by using the mobile terminal including the input device in the third embodiment according to the present invention.

FIG. 31A is a diagram showing the information which is displayed on the display unit when the character input operation is being performed in the relative position input method by using the mobile terminal including the input device in the third embodiment according to the present invention.

FIG. 31B is a diagram showing the information which is displayed on the display unit when the character input operation is being performed in the relative position input method by using the mobile terminal including the input device in the third embodiment according to the present invention.

FIG. 31C is a diagram showing the information which is displayed on the display unit when the character input operation is being performed in the relative position input method by using the mobile terminal including the input device in the third embodiment according to the present invention.

FIG. 31D is a diagram showing the information which is displayed on the display unit when the character input operation is being performed in the relative position input method by using the mobile terminal including the input device in the third embodiment according to the present invention.

FIG. 31E is a diagram showing the information which is displayed on the display unit when the character input operation is being performed in the relative position input method by using the mobile terminal including the input device in the third embodiment according to the present invention.

FIG. 31F is a diagram showing the information which is displayed on the display unit when the character input operation is being performed in the relative position input method by using the mobile terminal including the input device in the third embodiment according to the present invention.

FIG. 32A is a diagram showing a transition of a character which is selected from among the character information when a character is inputted according to the relative position input method.

FIG. 32B is a diagram showing the transition of the character which is selected from among the character information when the character is inputted according to the relative position input method.

FIG. 32C is a diagram showing the transition of the character which is selected from among the character information when the character is inputted according to the relative position input method.

FIG. 32D is a diagram showing the transition of the character which is selected from among the character information when the character is inputted according to the relative position input method.

FIG. 32E is a diagram showing the transition of the character which is selected from among the character information when the character is inputted according to the relative position input method.

FIG. 32F is a diagram showing the transition of the character which is selected from among the character information when the character is inputted according to the relative position input method.

FIG. 32G is a diagram showing the transition of the character which is selected from among the character information when the character is inputted according to the relative position input method.

FIG. 32H is a diagram showing the transition of the character which is selected from among the character information when the character is inputted according to the relative position input method.

FIG. 32I is a diagram showing the transition of the character which is selected from among the character information when the character is inputted according to the relative position input method.

FIG. 33A is a diagram showing a transition of a character which is selected from among the character information when a character is inputted according to the absolute position input method.

FIG. 33B is a diagram showing the transition of the character which is selected from among the character information when the character is inputted according to the absolute position input method.

FIG. 33C is a diagram showing the transition of the character which is selected from among the character information when the character is inputted according to the absolute position input method.

FIG. 33D is a diagram showing the transition of the character which is selected from among the character information when the character is inputted according to the absolute position input method.

FIG. 33E is a diagram showing the transition of the character which is selected from among the character information when the character is inputted according to the absolute position input method.

FIG. 33F is a diagram showing the transition of the character which is selected from among the character information when the character is inputted according to the absolute position input method.

FIG. 33G is a diagram showing the transition of the character which is selected from among the character information when the character is inputted according to the absolute position input method.

FIG. 33H is a diagram showing the transition of the character which is selected from among the character information when the character is inputted according to the absolute position input method.

FIG. 33I is a diagram showing the transition of the character which is selected from among the character information when the character is inputted according to the absolute position input method.

FIG. 34 is a flowchart showing operation content when a clear key has been depressed while the character input operation is being performed by using the mobile terminal including the input device in the third embodiment according to the present invention.

FIG. 35A is a diagram illustrating a process in which a character to be displayed first in a fixed frame when a mail function of the mobile terminal including the input device in the third embodiment according to the present invention has been activated is determined.

FIG. 35B is a diagram illustrating the process in which the character to be displayed first in the fixed frame when the mail function of the mobile terminal including the input device in the third embodiment according to the present invention has been activated is determined.

FIG. 35C is a diagram illustrating the process in which the character to be displayed first in the fixed frame when the mail function of the mobile terminal including the input device in the third embodiment according to the present invention has been activated is determined.

FIG. 36 is an external view of the mobile terminal including the input device in a fourth embodiment according to the present invention.

FIG. 37 is a block diagram showing the functional configuration of the input device in the fourth embodiment according to the present invention.

FIG. 38 is a diagram showing an example of the character information included in the storage unit included in the input device in the fourth embodiment according to the present invention.

FIG. 39 is a flowchart showing a procedure when a character is inputted according to the relative position input method by using the mobile terminal including the input device in the fourth embodiment according to the present invention.

FIG. 40A is a diagram showing a procedure when the input method is switched from the relative position input to the absolute position input by using the input device in the fourth embodiment according to the present invention.

FIG. 40B is a diagram showing the correspondence between the character-related information stored in the storage unit and the sections.

FIG. 41 is a flowchart showing a procedure for inputting a character according to the absolute position input method by using the mobile terminal including the input device in the fourth embodiment according to the present invention.

FIG. 42A is a diagram showing a transition of a character which is selected from among the character information when a character is inputted according to the relative position input method.

FIG. 42B is a diagram showing the transition of the character which is selected from among the character information when the character is inputted according to the relative position input method.

FIG. 42C is a diagram showing the transition of the character which is selected from among the character information when the character is inputted according to the relative position input method.

FIG. 42D is a diagram showing the transition of the character which is selected from among the character information when the character is inputted according to the relative position input method.

FIG. 42E is a diagram showing the transition of the character which is selected from among the character information when the character is inputted according to the relative position input method.

FIG. 42F is a diagram showing the transition of the character which is selected from among the character information when the character is inputted according to the relative position input method.

FIG. 42G is a diagram showing the transition of the character which is selected from among the character information when the character is inputted according to the relative position input method.

FIG. 42H is a diagram showing the transition of the character which is selected from among the character information when the character is inputted according to the relative position input method.

FIG. 42I is a diagram showing the transition of the character which is selected from among the character information when the character is inputted according to the relative position input method.

FIG. 43A is a diagram showing a transition of a character which is selected from among the character information when a character is inputted according to the absolute position input method.

FIG. 43B is a diagram showing the transition of the character which is selected from among the character information when the character is inputted according to the absolute position input method.

FIG. 43C is a diagram showing the transition of the character which is selected from among the character information when the character is inputted according to the absolute position input method.

FIG. 43D is a diagram showing the transition of the character which is selected from among the character information when the character is inputted according to the absolute position input method.

FIG. 43E is a diagram showing the transition of the character which is selected from among the character information when the character is inputted according to the absolute position input method.

FIG. 43F is a diagram showing the transition of the character which is selected from among the character information when the character is inputted according to the absolute position input method.

FIG. 43G is a diagram showing the transition of the character which is selected from among the character information when the character is inputted according to the absolute position input method.

FIG. 43H is a diagram showing the transition of the character which is selected from among the character information when the character is inputted according to the absolute position input method.

FIG. 43I is a diagram showing the transition of the character which is selected from among the character information when the character is inputted according to the absolute position input method.

FIG. 44A is a diagram showing an example of the information which is displayed on the display unit when the input operation is performed by using the mobile terminal including the input device in the fourth embodiment according to the present invention.

FIG. 44B is a diagram showing an example of the information which is displayed on the display unit when the input operation is performed by using the mobile terminal including the input device in the fourth embodiment according to the present invention.

FIG. 44C is a diagram showing an example of the information which is displayed on the display unit when the input operation is performed by using the mobile terminal including the input device in the fourth embodiment according to the present invention.

FIG. 45 is an external view of the mobile terminal including the input device in a fifth embodiment according to the present invention.

FIG. 46A is a cross-sectional diagram showing the structure of the input device in the fifth embodiment according to the present invention.

FIG. 46B is a cross-sectional diagram showing the structure of the input device in the fifth embodiment according to the present invention.

FIG. 47 is a block diagram showing the functional configuration of the input device in the fifth embodiment according to the present invention.

FIG. 48 is a flowchart showing a procedure when a character is inputted by using the mobile terminal including the input device in the fifth embodiment according to the present invention.

FIG. 49A is a diagram showing an example of the information which is displayed on the display unit when the input operation is performed by using the mobile terminal including the input device in the fifth embodiment according to the present invention.

FIG. 49B is a diagram showing an example of the information which is displayed on the display unit when the input operation is performed by using the mobile terminal including the input device in the fifth embodiment according to the present invention.

FIG. 49C is a diagram showing an example of the information which is displayed on the display unit when the input operation is performed by using the mobile terminal including the input device in the fifth embodiment according to the present invention.

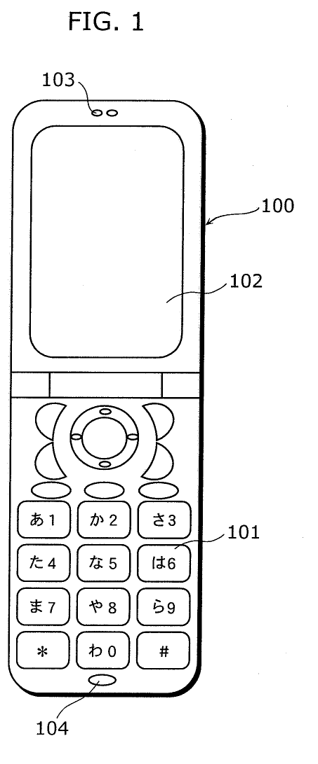

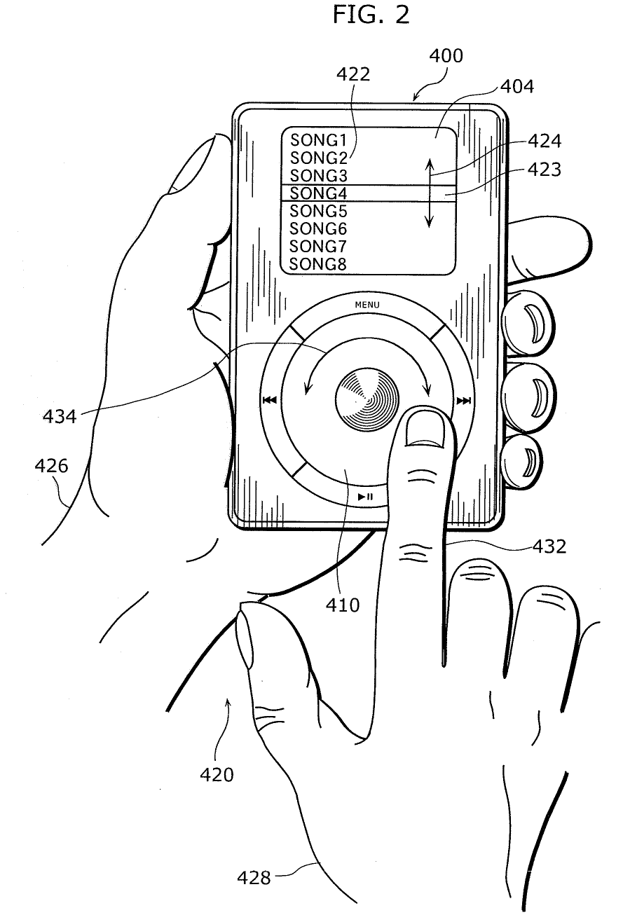

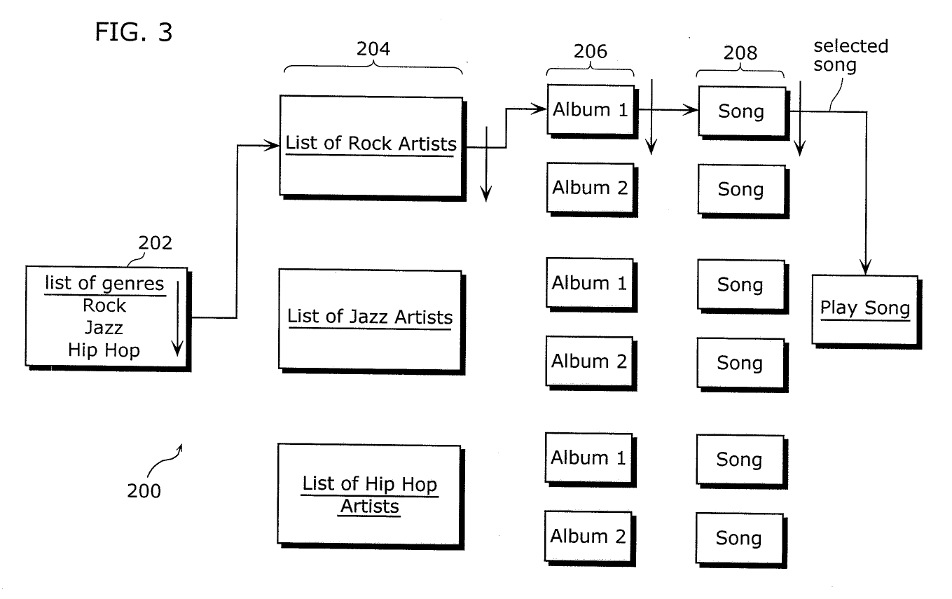

### NUMERICAL REFERENCES

1 Mobile terminal
2 Input device
3 Speaker
4 Speech input unit
5 Function invocation key
6 Display unit
8 Input unit
8a Contact point
9 Direction key
10 Determination key
11 Rotary encoder
12 Rotary shaft
13 Slit circular plate
14 Fixed slit
15 Light emitting device
16 Light receiving device
17, 84 Terminal
20, 30, 70 Character information
40, 65, 85 Wheel GUI
41 Fixed frame
42 Input screen
50 List
53 Selection frame
70 Contact sensing unit
71 Storage unit
72 Selection unit
73 Temporary storage unit
74 Pressing sensing unit
75 Confirmation unit
77 Movement sensing unit
77a Movement speed sensing unit
77b Amount of movement sensing unit
107, 183 Wheel button
108 Wheel unit
120 Rotation signal generation unit
121 Pressing unit
122 Rotation signal counting unit
123 Rotation direction detection unit
124 Pressing time judgment unit
125 Input method switching unit
126 Storage unit
127 First selection unit
128 Reference position setting unit
129 Second selection unit
131 Section information presentation unit
132 Information presentation unit
133 Confirmation unit
164 Number of times of pressing judgment unit
201-212, 301-312, 701-702 Line information

### BEST MODE FOR CARRYING OUT THE INVENTION

Hereinafter, preferred embodiments according to the present invention are described in detail with reference to the drawings. It should be noted that, in the following description and the respective drawings, the same reference characters are used for the same components and descriptions thereof are omitted.

### FIRST EMBODIMENT

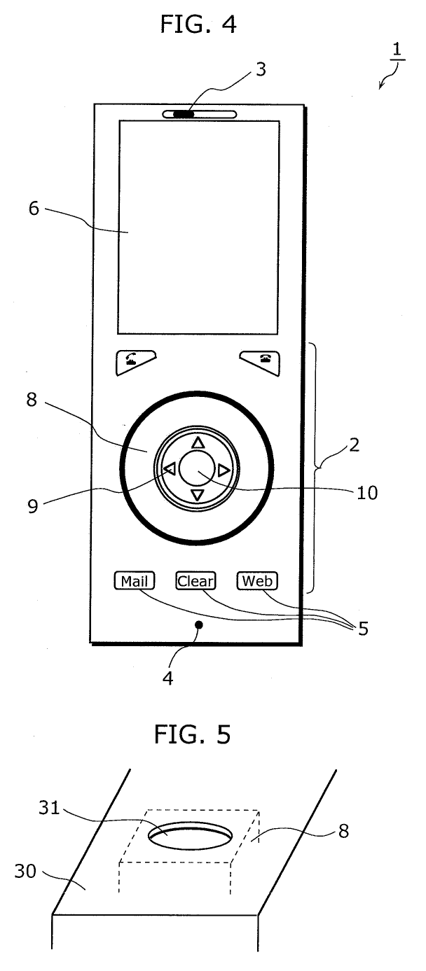

The present embodiment is described by using FIGS. 4 to 11.

FIG. 4 is an external view of a mobile terminal 1 including an input device 2 in a first embodiment of the present invention. This mobile terminal 1 is a communication terminal with a built-in antenna and includes functions which realize telephone calls, transmission and receiving of mails, Internet connections, and the like, and can communicate with another terminal or a base station. Moreover, when a mail function, an Internet browsing function, and other functions are used, it is possible to input characters by using the input device 2. Moreover, on a front face of the mobile terminal 1, a speaker 3 which outputs speech, a speech input unit 4 which inputs the speech, and a display unit 6 which causes various kinds of information to be displayed are included.

The input device 2 included in the mobile terminal 1 is a device which inputs information, and includes function invocation keys 5 for invoking the respective functions (the mail function, a telephone call function, a Web function, a clear function, and the like) of the mobile terminal 1, a pressible operation unit 8, a direction key 9 which selects a desired function or character from a plurality of the functions or the characters, and a determination key 10 which determines the selection by the direction key 9. On a surface of the operation unit 8, a touch sensor which senses contact of an object such as a finger or a touch pen is provided. A user uses this input device 2 to invoke the desired function or input the characters.

FIG. 5 is a diagram showing a relationship between the operation unit 8 and a cover 30 of the mobile terminal 1. In the figure, a portion denoted by a dotted line is the operation unit 8. As shown in this figure, the operation unit 8 is covered by the cover 30 of the mobile terminal 1. The surface of the operation unit 8 is rectangular, whereas an opening portion 31 formed on the cover 30 is circular. Hence, as shown in FIG. 4, when the mobile terminal 1 is seen from its front face, the surface of the operation unit 8 becomes circular. Of course, a shape of the surface of the operation unit 8 is not particularly limited, and may be rectangular or circular. A mechanical structure of the operation unit 8 is described later.

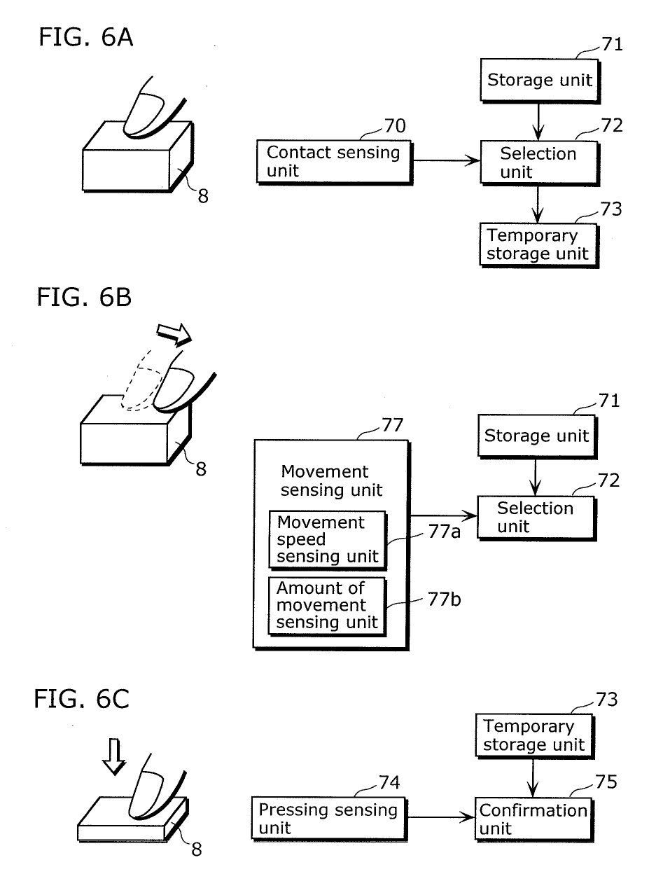

FIGS. 6A to 6C are functional block diagrams of the input device 2 in the first embodiment of the present invention. This input device 2 includes the operation unit 8, a contact sensing unit 70, a storage unit 71, a selection unit 72, a temporary storage unit 73, a pressing sensing unit 74, a confirmation unit 75, and a movement sensing unit 77.

The operation unit 8 is an input key or the like of a push style, which is operated by the user.

The contact sensing unit 70 is a touch sensor or the like which senses the contact of the finger to the surface of the operation unit 8.

The storage unit 71 is an example of an information set storage unit according to the present invention, and specifically, is a processing unit which stores information sets including a hierarchical structure with at least three layers, in a hierarchically corresponding manner. The information set is a collection of unit information, and the unit information is character-related information or function information. The character-related information is a generic name of the characters, numbers, and signs, and the function information is information related to the functions such as “mail”, “web”, “setting”, and “camera” which are included in the mobile terminal 1. Hereinafter, an information set to which unit information being selected by the user via the selection unit 72 belongs may be referred to as “selected target information set”.

The selection unit 72 is an example of a selection unit according to the present invention, and specifically, is a processing unit which selects predetermined unit information from among a predetermined information set, depending on a physical amount sensed by the movement sensing unit 77. The information selected in this way is temporarily stored in the temporary storage unit 73. Moreover, when it is sensed that the finger in contact with the surface of the operation unit 8 has moved on the surface of the operation unit 8, unit information which has been ranked following unit information being selected as input information, in the selected target information set, is selected as the input information. When the input information is selected in this way, input information which has been temporarily stored in the temporary storage unit 73 is updated to the input information which has been newly selected. In other words, even when the finger which has been in contact with the surface of the operation unit 8 leaves the surface of the operation unit 8 once, the information which has been temporarily stored in the temporary storage unit 73 is not lost. When the finger has contacted the surface of the operation unit 8 again, the information which has been temporarily stored in the temporary storage unit 73 is selected by the selection unit 72. By doing like this, a time required for selecting target information is reduced, and an input speed can be improved.

The movement sensing unit 77 is an example of a movement sensing unit according to the present invention, and specifically, is a processing unit which senses the physical amount related to the movement of the object (for example, the finger) in contact with the surface of the operation unit 8. The movement sensing unit 77 has a movement speed sensing unit 77a and an amount of movement sensing unit 77b. The movement speed sensing unit 77a senses a movement speed of the object in contact with the surface of the operation unit 8. The amount of movement sensing unit 77b senses an amount of movement of the object in contact with the surface of the operation unit 8.

Although details are described later, the selection unit 72 changes an amount of movement required for changing the unit information to be selected from among the information set, depending on the movement speed sensed by the movement speed sensing unit 77a. In other words, depending on the movement speed sensed by the movement speed sensing unit 77a becoming a low speed, an amount of movement required for changing a rank in the information set is set to a large value. Moreover, depending on the movement speed sensed by the movement speed sensing unit 77a becoming a high speed, the amount of movement required for changing the rank in the information set is set to a small value.

The pressing sensing unit 74 is an example of a pressing sensing unit according to the present invention, and specifically, is a processing unit which senses that the surface of the operation unit 8 is being pressed.

The confirmation unit 75 is an example of a confirmation unit according to the present invention, and specifically, is a processing unit which confirms the selection of the unit information being selected by the selection unit 72 (the unit information which has been stored in the temporary storage unit 73), when it is sensed by the pressing sensing unit 74 that the surface of the operation unit 8 has been pressed or that the pressing on the surface of the operation unit 8 has been released.

Although an indication in the figure has been omitted here, the input device 2 includes an image generation unit. This image generation unit is a processing unit which generates an image in which the unit information being selected by the selection unit 72 is being highlighted more than other unit information. The image generated by the image generation unit is displayed on the display unit 6 such as a liquid crystal display. A specific example of the image which is generated by the image generation unit is described later.

It should be noted that the selection unit 72, the confirmation unit 75, and the movement sensing unit 77 can be realized, for example, by executing programs by CPUs (Central Processing Units). The CPUs for realizing these respective units may be included as the same CPU in the mobile terminal 1. Moreover, the storage unit 71 and the temporary storage unit 73 can be realized, for example, by a medium such as a RAM (Random Access Memory), an HD (Hard Disc), or a flash memory. Storage units for realizing these respective units may be included as the same storage unit (such as the same RAM) in the mobile terminal 1.

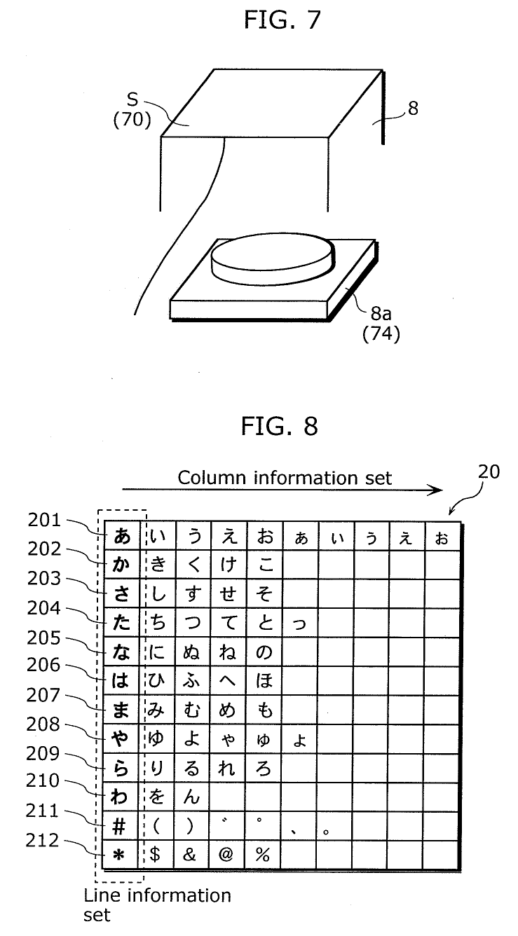

FIG. 7 is an explanatory diagram of the contact sensing unit 70 and the pressing sensing unit 74.

The contact sensing unit 70 is a unit for sensing whether or not the finger is in contact with the surface of the operation unit 8, and specifically, is a capacitance-type touch sensor S placed in the operation unit 8. In the capacitance-type touch sensor S, when a uniform voltage is applied to four corners of the sensor, a uniform electric field is generated on a surface of the sensor. When the user's finger touches in this state, capacitance changes in proportion to distances from the four corners of the sensor to the finger are generated, and therefore, it is possible to calculate a coordinate position of the finger based on the capacitance changes at the four corners. The contact sensing unit 70 performs judgment of whether or not the finger is touching, from sensed capacitance changes. The amount of movement sensing unit 77b calculates a change in X-Y coordinates of an area which the user is touching, from the capacitance changes sensed by the contact sensing unit 70, and senses the amount of movement based on the change and the like. The movement speed sensing unit 77a calculates the movement speed from the amount of movement which changes per unit time.

The pressing sensing unit 74 is a unit for sensing that the operation unit 8 has been pressed, and specifically, is a contact point 8a. In other words, in the present embodiment, an input key of a push type is employed. This input key of the push type is structurally one physical key, and has a mechanical movement in which a key top moves in upward and downward directions.

FIG. 8 is an example of character information 20 stored in the storage unit 71 in the present embodiment.

As shown in this figure, the character information 20 is made up of a line information set which is a collection of line information, and a column information set which is a collection of column information. Line information 201 to 212 is an example of unit information according to the present invention, and specifically, is line characters “ [symbol] (a)”, “ [symbol] (ka)”, “ [symbol] (sa)”, “ [symbol] (ta)”, “ [symbol] (na)”, “ [symbol] (ha)”, “ [symbol] (ma)”, “ [symbol] (ya)”, “ [symbol] (ra)”, “ [symbol] (wa)” at a beginning in a 50-character hiragana syllabary, and signs “#” and “*”. The line information set is an example of an information set according to the present invention, and specifically, is the collection of the line information “ [symbol] (a) [symbol] (ka) [symbol] (sa) [symbol] (ta) [symbol] (na) [symbol] (ha) [symbol] (ma) [symbol] (ya) [symbol] (ra) [symbol] (wa)#*”. The column information is an example of the unit information according to the present invention, and specifically, is column characters in the 50-character hiragana syllabary (for example, “ [symbol] (a)”, “ [symbol] (i)”, “ [symbol] (u)”, “ [symbol] (e)”, and “ [symbol] (o)” when the line information is “ [symbol] (a)”, and “ [symbol] (ka)”, “ [symbol] (ki)”, “<(ku)”, “ [symbol] (ke)”, and “ [symbol] (ko)” when the line information is “ [symbol] (ka)”). The column information set is an example of the information set according to the present invention, and specifically, is the collection of the column information (for example, “ [symbol] (a) [symbol] (i) [symbol] (u) [symbol] (e) [symbol] (o)” when the line information is “ [symbol] (a)”, and “ [symbol] [symbol] (ka) [symbol] (ki) [symbol] (ku) [symbol] (ke) [symbol] (ko)” when the line information is “ [symbol] (ka)”).

FIG. 9 is a diagram conceptually representing a condition in which the information sets have been hierarchically stored in the storage unit 71 in the present embodiment. Here, the information sets including a hierarchical structure with four layers have been stored. “Lowest layer” to be described below is an example of “n-th layer” according to the present invention, and moreover, “middle layer” to be described below is an example of “m-th layer” according to the present invention. It should be noted that “m-th layer” of the present invention is defined as a layer positioned in the middle between a highest layer and “n-th layer”.

In the highest layer, an information set T11 has been stored. The information set T11 is a function information set, and specifically, is a collection of function information “mail”, “music”, “web”, “camera”, “application”, “tool”, and “setting”. In a second layer, an information set T12 has been stored. The information set T12 is a function information set which has been associated with the function information “setting” belonging to the highest layer, and specifically, is a collection of function information “memo pad”, “calculator”, “schedule”, “clock”, “infrared reception”, “barcode recognition”, and “software update”. In a third layer, an information set T13 has been stored. The information set T13 is a line information set which has been associated with the function information “memo pad” belonging to the second layer, and specifically, is the collection of the line information [symbol] (a)”, “ [symbol] (ka)”, “ [symbol] (sa)”, “ [symbol] (ta)”, “ [symbol] (na)”, and the like. In the lowest layer, information sets T14-1, T14-2, and the like have been stored. The information set T14-1 is a column information set which has been associated with the line information “ [symbol] (a)” belonging to the third layer, and specifically, is the collection of the column information “ [symbol] (a)”, “ [symbol] (i)”, “ [symbol] (u)”, “ [symbol] (e)”, and “ [symbol] (o)”. The information set T14-2 is a column information set which has been associated with the line information “ [symbol] (ka)” belonging to the third layer, and specifically, is the collection of the column information “ [symbol] (ka)”, “ [symbol] (ki)”, “<(ku)”, “ [symbol] (ke)”, and “ [symbol] (ko)”.

As shown in this FIG. 9, in the present embodiment, after transitions from the highest layer to the second layer, from the second layer to the third layer, and from the third layer to the lowest layer, there is a transition from the lowest layer to the third layer. In other words, when the selection of the predetermined unit information from among the predetermined information set is confirmed by the confirmation unit 75, the selection unit 72 shifts to a state in which the unit information is selected from among the information set which has been associated with this predetermined unit information. Then, when the selection of the predetermined unit information from among the information set in the lowest layer is confirmed by the confirmation unit 75, the selection unit 72 shifts to a state in which the unit information is selected from among the information set in the middle layer (here, the third layer) between the highest layer and the lowest layer.

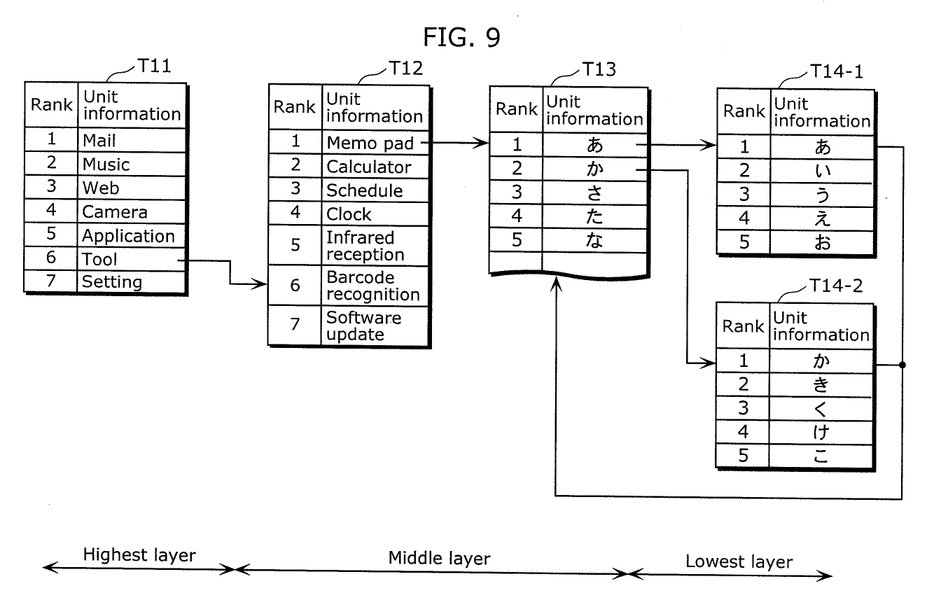

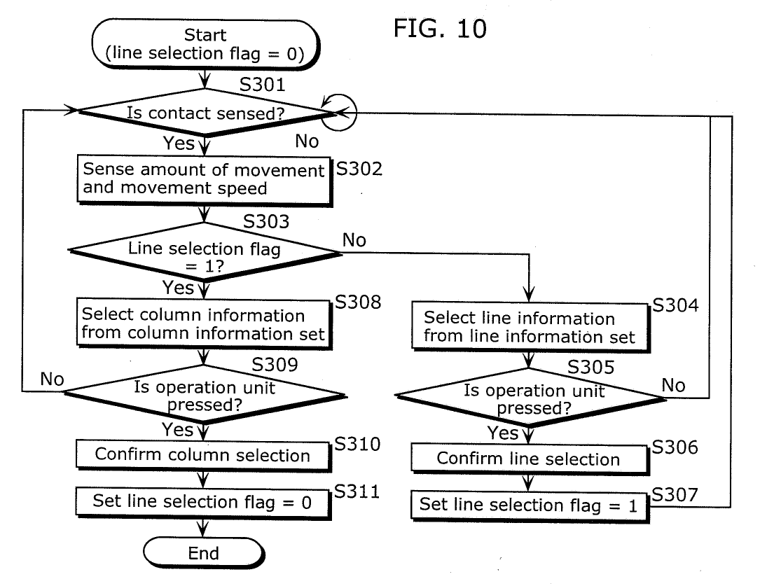

FIG. 10 is a flowchart showing a procedure when a character is inputted by using the mobile terminal 1 in the present embodiment, and shows a procedure after the function information “memo pad” belonging to the second layer has been selected. Hereinafter, a series of flows until the selection unit 72 selects the information from the storage unit 71 and the confirmation unit 75 confirms selection of a target character is described.

First, when the user touches the surface of the operation unit 8 with the finger, the contact sensing unit 70 senses the contact of the finger (S301: Yes), and when the user moves the finger touching the surface of the operation unit 8, the movement speed sensing unit 77a and the amount of movement sensing unit 77b sense the movement speed and the amount of movement of the finger (S302).

Next, based on the movement speed and the amount of movement, when a line selection flag is 1, the selection unit 72 changes a rank of the column information stored in the storage unit 71 and thereby selects the column information (S303: Yes, S308), and when the line selection flag is 0, the selection unit 72 changes a rank of the line information stored in the storage unit 71 and thereby selects the line information (S303: No, S304).

Here, when the user uses a character input function, it is assumed that 0 has been given to the line selection flag as an initial value. In other words, when the user starts using the character input function of the mobile terminal 1, it is assumed that, first, desired line information is selected from the line information set, and next, the column information associated with the above described selected line information is selected. By doing like this, since the column information set is ranked after the line information set, the user performs the character input in an order in which the line information is selected and subsequently the column information is selected.

Hereinafter, the description is continued in a state in which the line selection flag has been set to 0 (S303: No).

The line information selected by the selection unit 72 is stored in the temporary storage unit 73. When the user presses the operation unit 8 and the pressing sensing unit 74 senses the pressing on the operation unit 8, the confirmation unit 75 confirms the selection of the line information stored in the temporary storage unit 73 (S305: Yes, S306).

On the other hand, when the pressing sensing unit 74 does not sense the pressing on the operation unit 8, and the contact sensing unit 70 and the movement sensing unit 77 sense the movement of the user's finger, the selection unit 72 selects the line information again based on the movement speed and the amount of movement, and changes the line information stored in the temporary storage unit 73 (S305: No).

When the confirmation unit 75 confirms the selection of the line information stored in the temporary storage unit 73, 1 is set to the line selection flag (S307). Thereby, the selected target information set shifts to the column information set which has been is ranked following the line information set.

Also in the selection of the column information, similarly to the selection of the line information, based on the amount of movement and the movement speed of the finger sensed by the movement sensing unit 77, the rank of the column information stored in the storage unit 71 is changed, and thereby the column information is selected. Then, the above described selected column information is stored in the temporary storage unit 73, and when the pressing sensing unit 74 senses the pressing on the operation unit 8, the confirmation unit 75 confirms the selection of the column information stored in the temporary storage unit 73 (S301, S302, S303: Yes, S308, S309: Yes, S310).

When the confirmation unit 75 confirms the selection of the column information stored in the temporary storage unit 73, 0 is set to the line selection flag (S311). Thereby, the selected target information set shifts to the line information set which has been ranked prior to the column information set. In other words, in the case where a hierarchical structure has been configured in which the column information is selected after the selection of the line information, the selected target information set shifts from the line information set which is upper to the column information set which is lower with the pressing on the operation unit 8, which thereby enables the selection of a lower information set. Not only that, it is also possible to shift the selected target information set from the column information set which is lower to the line information set which is upper, by an exactly similar operation.

In this way, it is possible to change the selected target information set from the lower information set to an upper information set without requiring a special operation. Thereby, it is possible to save an effort of searching the upper information set after the input in the lower information set has been confirmed, and therefore, an operational burden is reduced and the input speed is improved.

It should be noted that, in the present embodiment, although it is assumed that the line selection flag included within the input device 2 is composed of software, the line selection flag may be composed of hardware. For example, the operation unit 8 can also be composed of a so-called tact switch or the like. In this case, the line selection flag may be set to “1” when the operation unit 8 is in a state of being electrically energized with a circuit included in the input device 2, and the line selection flag may be set to “0” in an insulating state.

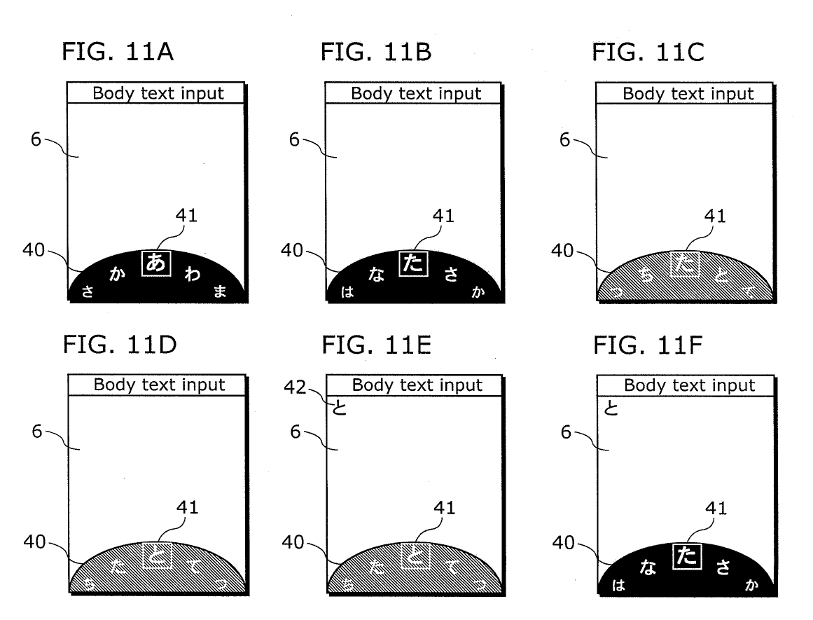

FIGS. 11A to 11F are diagrams showing an example of information which is displayed on the display unit 6 when an input operation is being performed by using the mobile terminal 1 in the present embodiment. Here, a series of flows in which the information selected by the selection unit 72 is displayed on the display unit 6 is mainly described.

When the user performs a character input operation, a generally semicircular-shaped wheel GUI (Graphical User Interface) 40 is displayed on the display unit 6. In other words, a character being selected by the selection unit 72 (that is, a character stored in the temporary storage unit 73) is displayed in a fixed frame 41 on the wheel GUI, and information adjacent to the character being selected by the selection unit 72 is also displayed on the wheel GUI 40 in such a manner in which a circular arc is drawn. In this way, when a configuration in which not only the selected character but also characters next thereto are displayed is employed, the user can also check characters previous and next to the character being selected.

Hereinafter, an operation when “ [symbol] (to)” of hiragana is inputted is described by using FIGS. 11A to 11F.

First, as shown in FIG. 11A, the ranked line information set is displayed on the wheel GUI 40. Here, a condition is shown in which the line information “ [symbol] (a)” of a beginning rank and line information “ [symbol] (wa)” of a last rank in the line information set are displayed in a side-by-side manner, and the line information “ [symbol] (a)” of the beginning rank is being selected.

At this time, when the user moves the finger on the operation unit 8, based on the amount of movement and the movement speed of the finger sensed by the movement sensing unit 77, the selection unit 72 changes the rank of the line information constituting the line information set, and thereby selects the line information. Then, the above described selected line information is displayed in the fixed frame 41, and adjacent line information is displayed on the wheel GUI. In this way, FIG. 11B shows a condition in which the rank is changed from the line information “ [symbol] (a)” to “ [symbol] (ka)” and “ [symbol] (sa)”, and “ [symbol] (ta)” is being selected.

Here, when the user presses the operation unit 8, the pressing sensing unit 74 senses the pressing, and the confirmation unit 75 confirms the selection of “ [symbol] (ta)” stored in the temporary storage unit 73 and changes a color of the wheel GUI. Along with this confirmation, the selection unit 72 changes the rank of the information set to the column information associated with the selected line information, thereby shifts the selected target information set, and displays the selected target information set on the display unit 6 (FIG. 11C).

In this way, in the case where the color of the wheel GUI is changed when the selected target information set has been changed, the user can easily comprehend which information set has become the selected target information set. In other words, the display may be any display from which the user can recognize which information set has been set as the selected target information set.

Subsequently, when the user moves the finger on the operation unit 8, based on the amount of movement and the movement speed of the finger sensed by the movement sensing unit 77, the selection unit 72 changes the rank of the column information constituting the column information set, and thereby selects the column information. Then, the above described selected column information is displayed in the fixed frame 41, and adjacent column information is displayed on the wheel GUI. In this way, FIG. 11D shows a condition in which the rank is changed from the column information “ [symbol] (ta)” to “ [symbol] (chi)”, “ [symbol] (tsu)”, and “ [symbol] (te)”, and “ [symbol] (to)” is being selected.

Here, when the user presses the operation unit 8, the pressing sensing unit 74 senses the pressing, and the confirmation unit 75 confirms the selection of “ [symbol] (to)” stored in the temporary storage unit 73 and displays “ [symbol] (to)” on an input screen 42 (FIG. 11E). When the selection in the column information set is confirmed, the selection unit 72 changes the rank of the information set, thereby shifts the selected target information set to the line information set, displays the line information set on the display unit 6, and also changes the color of the wheel GUI (FIG. 11F). Thereby, only by pressing the operation unit 8, the selected target information set shifts to the line information set which has been ranked prior to the column information set. In other words, in the case where the hierarchical structure has been configured in which the column information is selected after the selection of the line information, the selected target information set shifts from the line information set which is upper to the column information set which is lower with the pressing on the operation unit 8, which thereby enables the selection of the lower information set. Not only that, it is also possible to shift the selected target information set from the column information set which is lower to the line information set which is upper, by the exactly similar operation.

In this way, it is possible to change the selected target information set from the lower information set to the upper information set without requiring the special operation. Thereby, it is possible to save the effort of searching the upper information set after the input in the lower information set has been confirmed, and therefore, the operational burden is reduced and the input speed is improved.

Moreover, the characters constituting the information set which has become the selected target information set are displayed on the wheel GUI 40. Thereby, the user can easily input a desired character while seeing the display unit 6, without feeling the operational burden.

### SECOND EMBODIMENT

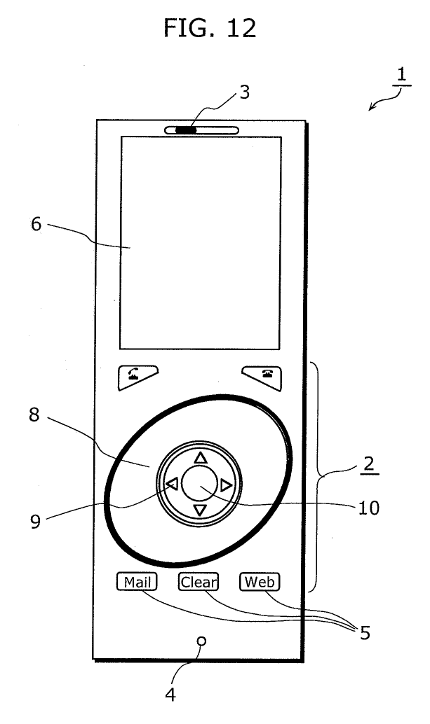

Although a case where the character is inputted has been described in the above described first embodiment, a case where a tune is played is mainly described in the present second embodiment. Hereinafter, the present second embodiment is described with a focus on different points from the above described first embodiment, by using FIGS. 12 to 23. The same reference characters are used for components similar to the above described first embodiment, and descriptions thereof are omitted.

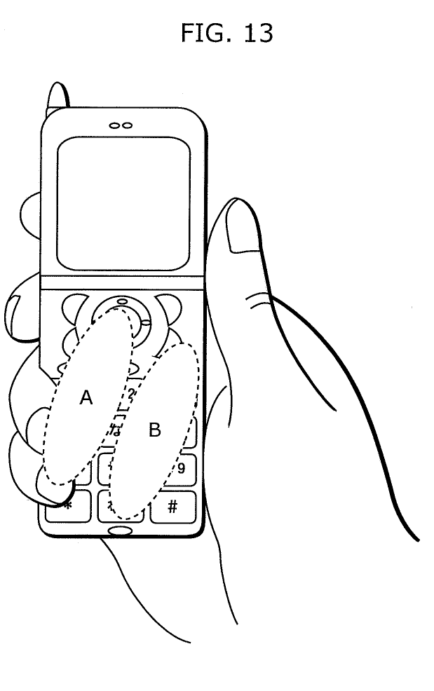

FIG. 12 is an external view of the mobile terminal 1 including the input device 2 in the second embodiment of the present invention. The configuration of this mobile terminal 1 is the same as the above described first embodiment, except for a point in which the operation unit 8 included in the input device 2 has become an elliptical type. When the operation unit 8 has an elliptical shape in this way, since an arrangement becomes to be along a path of the movement of the user's finger, a burden on the user at the time of the operation is reduced, and an operational efficiency is improved. In other words, as shown in FIG. 13, in the case where the user is operating the mobile terminal with the right hand, his thumb is extended when the user is operating an area of A, which imposes a small burden on the hand and the thumb. On the other hand, when the user is operating an area of B, the thumb is bent in a cramped posture, which thereby imposes a large burden on the thumb. Consequently, when operations at a position near the thumb can be reduced as much as possible by causing the operation unit 8 to have the elliptical shape, the burden on the user at the time of the operation is reduced, and the operational efficiency is improved.

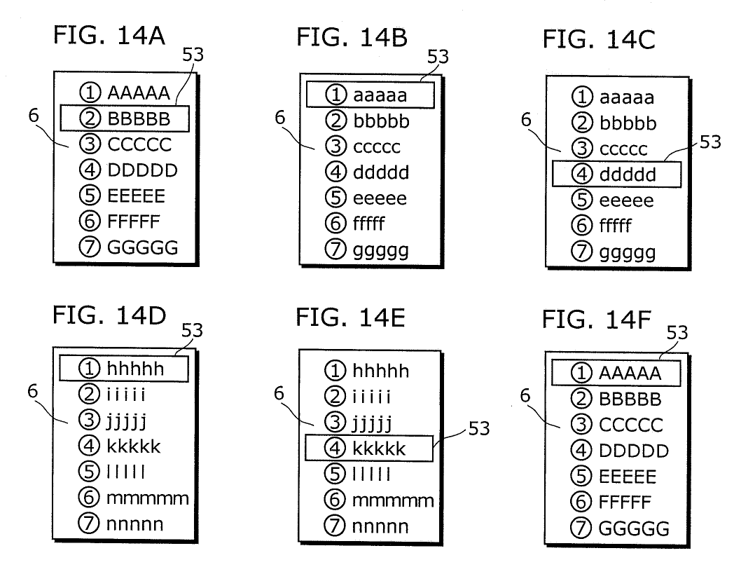

FIGS. 14A to 14F are diagrams showing an example of the information which is displayed on the display unit 6 when the input operation is being performed by using the mobile terminal 1 in the present embodiment. Here, a series of flows in which the information selected by the selection unit 72 is displayed on the display unit 6 is mainly described.

On the display unit 6, unit information (for example, the function information, music information, or the like) constituting one information set is displayed. Among these pieces of the unit information, the unit information being selected by the selection unit 72 is displayed so as to be surrounded by a selection frame 53. Hereinafter, an information selection operation is described by using FIGS. 14A to 14F.

First, as shown in FIG. 14A, a first information set is displayed on the display unit 6. At this time, when the user moves the finger on the operation unit 8, based on the amount of movement and the movement speed of the finger sensed by the movement sensing unit 77, the selection unit 72 changes a rank of the information and thereby selects the information, and the selection frame 53 moves to the above described selected information. Here, when the user presses the operation unit 8, the pressing sensing unit 74 senses the pressing, and the confirmation unit 75 confirms the selection of the information stored in the temporary storage unit 73. Along with this confirmation, the selection unit 72 changes the rank to a second information set associated with the selected information, thereby shifts the selected target information set, and displays the selected target information set on the display unit 6 (FIG. 14B).

Subsequently, when the user moves the finger on the operation unit 8, based on the amount of movement and the movement speed of the finger sensed by the movement sensing unit 77, the selection unit 72 changes a rank of information constituting the second information set and thereby selects the information, and the selection frame 53 moves to the above described selected information (FIG. 14C).

Here, when the user presses the operation unit 8, the pressing sensing unit 74 senses the pressing, and the confirmation unit 75 confirms the selection of the information stored in the temporary storage unit 73. When the selection in the second information set is confirmed, the selection unit 72 changes the rank of the information set, thereby shifts the selected target information set to a third information set, and displays the third information set on the display unit 6 (FIG. 14D).

Furthermore, when the user moves the finger on the operation unit 8, based on the amount of movement and the movement speed of the finger sensed by the movement sensing unit 77, the selection unit 72 changes a rank of information constituting the third information set and thereby selects the information, and the selection frame 53 moves to the above described selected information (FIG. 14E).

Here, when the user presses the operation unit 8, the pressing sensing unit 74 senses the pressing, and the confirmation unit 75 confirms the selection of the information stored in the temporary storage unit 73. When the selection in the third information set is confirmed in this way, the selection unit 72 changes the rank of the information set, thereby shifts the selected target information set to the first information set, and displays the first information set on the display unit 6 (FIG. 14F).

Thereby, only by pressing the operation unit 8, the selected target information set shifts to the first information set which has been ranked prior to the third information set. In other words, in the case where a hierarchical structure has been configured in which the information constituting the second information set is selected after the selection of the information constituting the first information set, and the information constituting the third information set is selected after the selection of the information constituting the second information set, the selected target information set shifts from the first information set which is upper to the second information set and the third information set which are lower with the pressing on the operation unit 8, which thereby enables the selection of the lower information set. Not only that, it is also possible to shift the selected target information set from the column information set which is lower to the line information set which is upper, by the exactly similar operation.

In this way, it is possible to change the selected target information set from the lower information set to the upper information set without requiring the special operation. Thereby, it is possible to save the effort of searching the information set of an upper rank after the input in the lower information set has been confirmed, and therefore, the operational burden is reduced and the input speed is improved.

It should be noted that, in the present embodiment, although it has been assumed that the selected target information set shifts to the first information set after the selection of the information constituting the third information set has been confirmed, the present invention is not limited thereto. In other words, after the selection of the information constituting the third information set has been confirmed, the selected target information set may shift to the second information set.

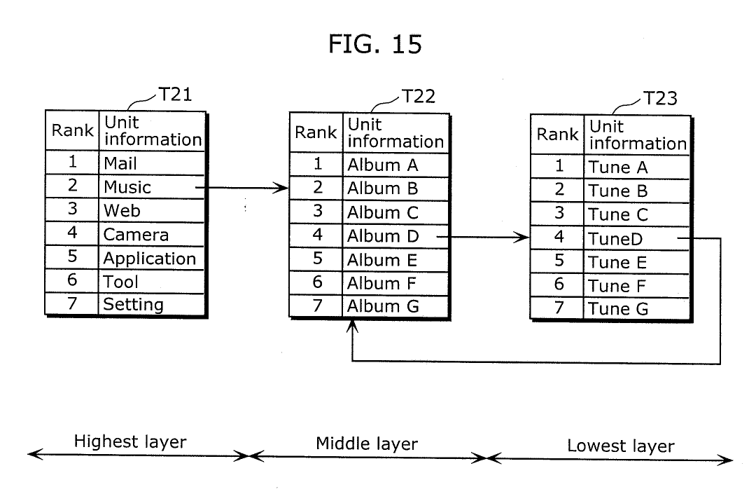

FIG. 15 is a diagram conceptually representing a condition in which the information sets have been hierarchically stored in the storage unit 71 in the present embodiment. Here, the information sets including a hierarchical structure with three layers have been stored.

In a highest layer, an information set T21 has been stored. The information set T21 is the function information set, and specifically, is the collection of the function information “mail”, “music”, “web”, “camera”, “application”, “tool”, and “setting”. In a second layer, an information set T22 has been stored. The information set T22 is an album information set which has been associated with the function information “music” belonging to the highest layer, and specifically, is a collection of “album A” to “album G”. In a lowest layer, an information set T23 has been stored. The information set T23 is a tune information set which has been associated with “album D” belonging to the second layer, and specifically, is a collection of “tune A” to “tune G”. As shown in this FIG. 15, after transitions from the highest layer to the second layer, and from the second layer to the lowest layer, there may be a transition from the lowest layer to the second layer.

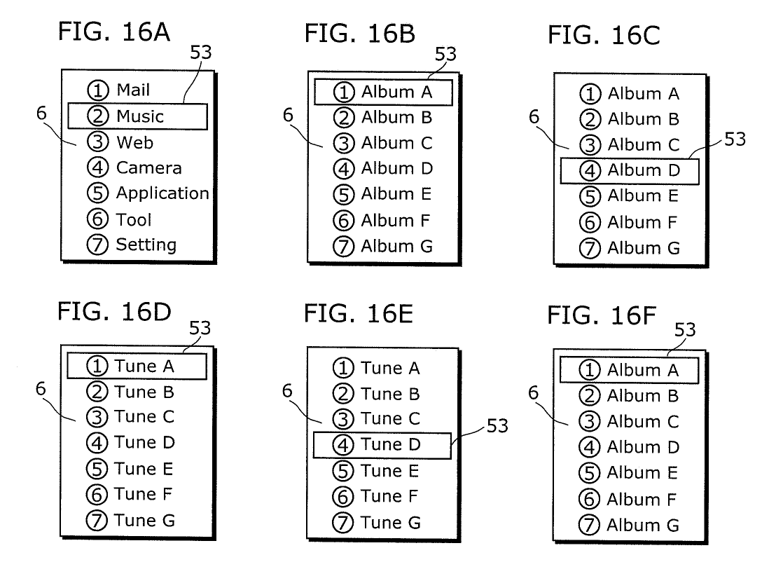

FIGS. 16A to 16F are diagrams showing an example of the information which is displayed on the display unit 6 when the input operation is being performed by using the mobile terminal 1 in the present embodiment. Here, as shown in FIG. 15, a case where the three information sets T21 to T23 have been hierarchically stored in the storage unit 71 is assumed and described.

First, as shown in FIG. 16A, the information set T21 is displayed on the display unit 6. At this time, when the user moves the finger on the operation unit 8, based on the amount of movement and the movement speed of the finger sensed by the movement sensing unit 77, the selection unit 72 changes a rank of the information and thereby selects “music”, and the selection frame 53 moves to the above described selected “music”. Here, when the user presses the operation unit 8, the pressing sensing unit 74 senses the pressing, and the confirmation unit 75 confirms the selection of “music” stored in the temporary storage unit 73. Along with this confirmation, the selection unit 72 changes the rank to the information set T22 associated with the selected “music”, thereby shifts the selected target information set, and displays the selected target information set on the display unit 6 (FIG. 16B).

Subsequently, when the user moves the finger on the operation unit 8, based on the amount of movement and the movement speed of the finger sensed by the movement sensing unit 77, the selection unit 72 changes a rank of information constituting the information set T22 and thereby selects “album D”, and the selection frame 53 moves to the above described selected “album D” (FIG. 16C).

Here, when the user presses the operation unit 8, the pressing sensing unit 74 senses the pressing, and the confirmation unit 75 confirms the selection of “album D” stored in the temporary storage unit 73. Along with this confirmation, the selection unit 72 changes the rank to the information set T23 associated with the selected “album D”, thereby shifts the selected target information set, and displays the selected target information set on the display unit 6 (FIG. 16D).

Furthermore, when the user moves the finger on the operation unit 8, based on the amount of movement and the movement speed of the finger sensed by the movement sensing unit 77, the selection unit 72 changes a rank of information constituting the information set T23 and thereby selects “tune D”, and the selection frame 53 moves to the above described selected “tune D” (FIG. 16E).

Here, when the user presses the operation unit 8, the pressing sensing unit 74 senses the pressing, and the confirmation unit 75 confirms the selection of “tune D” stored in the temporary storage unit 73. When the selection in the information set T23 is confirmed in this way, the selection unit 72 changes the rank of the information set, thereby shifts the selected target information set to the information set T22, and displays the information set T22 on the display unit 6 (FIG. 16F).

As described above, according to the mobile terminal 1 including the input device 2 in the second embodiment of the present invention, when the selection of the album is confirmed, there is a shift to a state in which the tune belonging to that album is selected, and when the selection of the tune is confirmed, there is a shift to a state in which the album is selected. Therefore, after play of one song has been completed, when a song belonging to an album different from that song is desired to be played, it is not necessary to perform an operation for a transition in a hierarchy. In other words, even when a large amount of information is managed with a menu having a hierarchical structure, it becomes possible for the user to efficiently find target information.

It should be noted that, in the above description, although it has been assumed that when the selection of a music album is confirmed, there is the shift to the state in which the tune belonging to that music album is selected, and when the selection of the tune is confirmed, there is the shift to the state in which the music album is selected, kinds of the information sets to be handled are not limited.

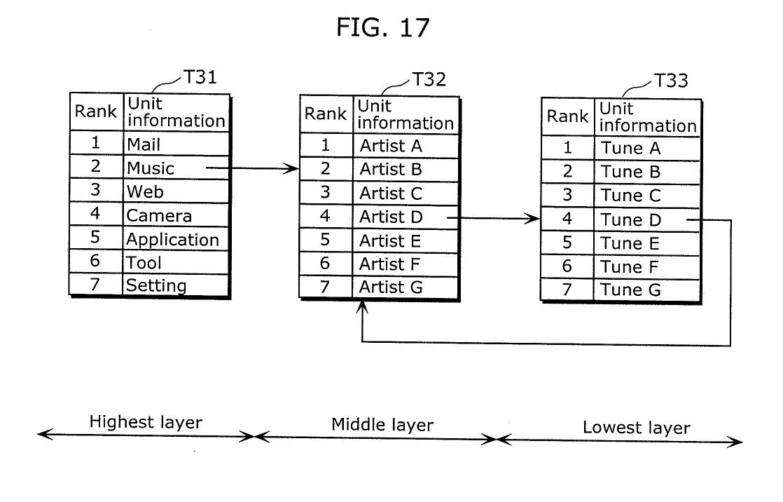

FIG. 17 is a diagram showing hierarchical association of other information sets. As shown in this figure, an information set T32 belonging to a middle layer may be a collection of unit information indicating an artist. An information set T31 belonging to the highest layer is the same as the information set T21 in FIG. 15, and an information set T33 belonging to the lowest layer is the same as the information set T23 in FIG. 15. Thereby, in the case where a music function is selected and the tune is played, it becomes possible to, when selection of an artist is confirmed, shift to a state in which the tune belonging to that artist is selected, and when the selection of the tune is confirmed, shift to a state in which the artist is selected.

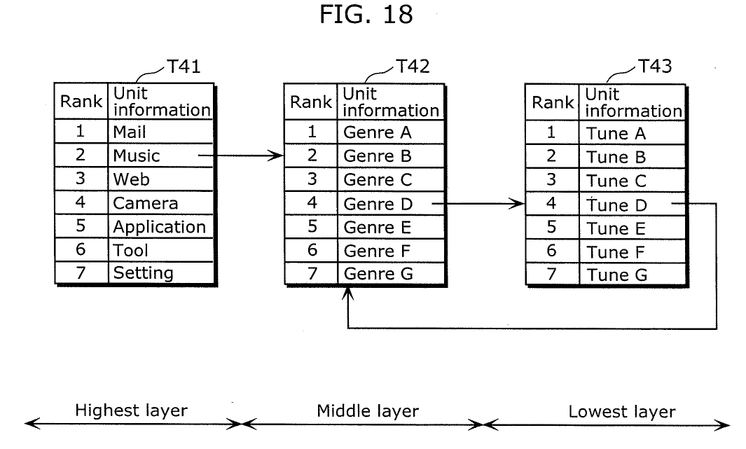

FIG. 18 is a diagram showing hierarchical association of other information sets. As shown in this figure, an information set T42 belonging to the middle layer may be a collection of unit information indicating a music genre. An information set T41 belonging to the highest layer is the same as the information set T21 in FIG. 15, and an information set T43 belonging to the lowest layer is the same as the information set T23 in FIG. 15. Thereby, in the case where the music function is selected and the tune is played, it becomes possible to, when selection of a music genre is confirmed, shift to a state in which the tune constituting that music genre is selected, and when the selection of the tune is confirmed, shift to a state in which the music genre is selected.

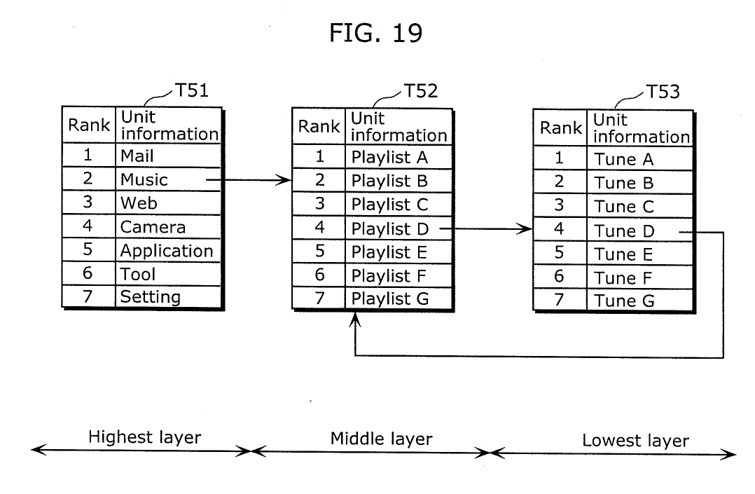

FIG. 19 is a diagram showing hierarchical association of other information sets. As shown in this figure, an information set T52 belonging to the middle layer may be a collection of unit information indicating a music playlist. An information set T51 belonging to the highest layer is the same as the information set T21 in FIG. 15, and an information set T53 belonging to the lowest layer is the same as the information set T23 in FIG. 15. Thereby, in the case where the music function is selected and the tune is played, it becomes possible to, when selection of a music playlist is confirmed, shift to a state in which the tune belonging to that music playlist is selected, and when the selection of the tune is confirmed, shift to a state in which the music playlist is selected.

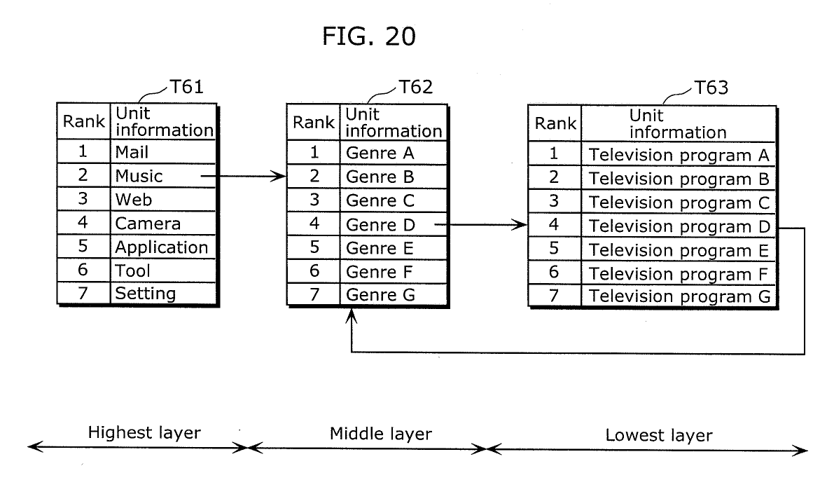

FIG. 20 is a diagram showing hierarchical association of other information sets. As shown in this figure, an information set T61 belonging to the highest layer is the same as the information set T21 in FIG. 15, except for a point in which the music function has been replaced with a television function. An information set T62 belonging to the middle layer is a genre information set associated with function information “television” belonging to the highest layer. An information set T63 belonging to the lowest layer is a television program information set associated with “genre D” belonging to the middle layer. Thereby, in the case where the television function is selected and a television program is played, it becomes possible to, when selection of a television program genre is confirmed, shift to a state in which the television program constituting that genre is selected, and when the selection of the television program is confirmed, shift to a state in which the television program genre is selected.

It should be noted that, here, although a three-hierarchical structure in which there is the transition from the lowest layer to the second layer has been illustrated, the number of layers and the hierarchical structure are not limited thereto. For example, a hierarchical structure with at least four layers may be included in which a highest layer is a genre layer, a second layer is an artist layer, a third layer is an album layer, and a lowest layer is a tune layer. In this case, there may be a transition from the tune layer to the artist layer, or there may be a transition from the tune layer to the album layer. In other words, any configuration in which there is the transition to the middle layer when the selection of the information is confirmed in the lowest layer is included in the applicable scope of the present invention. When the middle layer is made up of a plurality of layers, regarding which layer the transition is performed to, a determination may be freely made in terms of usability. In other words, the layer which becomes a transition target may have been previously determined depending on an intended use and the like of the above described device, or may be able to be freely changed by the user depending on preferences.

It should be noted that, in the above description, although the input key of the push style which includes the touch sensor has been employed as the operation unit 8, a mode of the operation unit 8 is not limited thereto. In other words, as described below, a rotary body can also be employed as the operation unit 8.

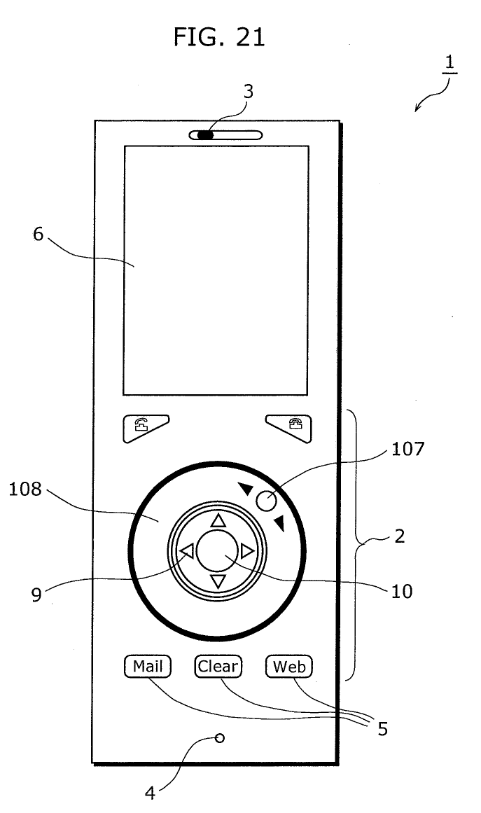

FIG. 21 is an external view of the mobile terminal 1 including the input device 2 in the second embodiment according to the present invention. As shown in this figure, the input device 2 in the present second embodiment has a rotary body 108 as the operation unit 8.

This mobile terminal 1 is the communication terminal with the built-in antenna and includes the functions which realize the telephone calls, the transmission and the receiving of the mails, the Internet connections, and the like, and can communicate with another terminal or the base station. Moreover, when the mail function, the Internet browsing function, and other functions are used, it is possible to input the characters by using the input device 2. Moreover, on the front face of the mobile terminal 1, the speaker 3 which outputs the speech, the speech input unit 4 which inputs the speech, and the display unit 6 which causes the various kinds of information to be displayed are included.

The input device 2 included in the mobile terminal 1 is composed of the function invocation keys 5 for invoking the respective functions (for example, the mail function, the telephone call function, the Web function, the clear function, and the like) of the mobile terminal 1, a wheel unit 108 which is freely rotatable within a plane in parallel with a housing of the mobile terminal 1, a depressible wheel button 107 included on the wheel unit 108, the direction key 9 which selects the desired function or character from the plurality of the functions or the characters, and the determination key 10 which determines the selection by the direction key 9. The user uses this input device 2 to invoke the desired function or input the characters.

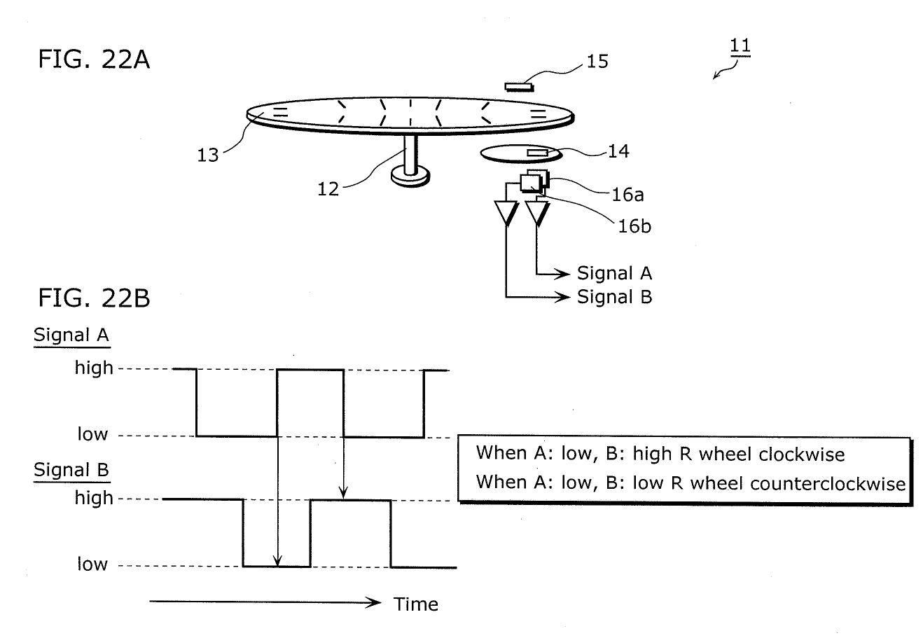

FIG. 22A is a diagram for illustrating a configuration of the wheel unit 108 of the input device 2 in the present embodiment, and FIG. 22B is a diagram schematically representing signals outputted by a rotary encoder 11 of the wheel unit 108. The wheel unit 108 has the rotary encoder 11 of a so-called incremental type, which converts a mechanical rotational displacement into an electrical pulse.

As shown in FIG. 22A, a rotary shaft 12 of the rotary encoder 11 is attached with a slit circular plate 13 graduated in a lattice manner at regular intervals, and relative to this, a fixed slit 14 graduated at the same intervals is fixed. A light emitting device 15 and light receiving devices 16a and 16b are placed with this fixed slit 14 interposed therebetween, and a light path of light emitted from the light emitting device 15 is interrupted for each slit pitch by rotation of the rotary shaft 12, and lighting and darkening of the number of times in proportion to an amount of rotation are repeated. These lighting and darkening are retrieved as an electrical signal by the light receiving devices 16a and 16b. As shown in a signal A and a signal B of FIG. 22B, this output signal is a two-phase signal in which phases have been adjusted so as to be shifted for 1/4 pitch from each other, and inversion of a rotation direction also inverts these phases, and it is possible to perform addition and subtraction for the amount of rotation, in combination with a reversible counter (not shown) having a direction discrimination circuit.

In other words, as shown in FIG. 22B, in the case where the signal A has been set as a reference signal, it can be discriminated that the wheel unit 108 is rotating clockwise when the signal B is “High” at a timing when the signal A becomes “Low”, and that the wheel unit 108 is rotating counterclockwise when the signal B is “Low” at the timing when the signal A becomes “Low”.

In the present embodiment, although the description is performed by using the rotary encoder of a photoelectric method as described above, rotary encoders of other methods may be used. As other methods, a magnetic method, an electrostatic method, a contact method, and the like are representative thereof.

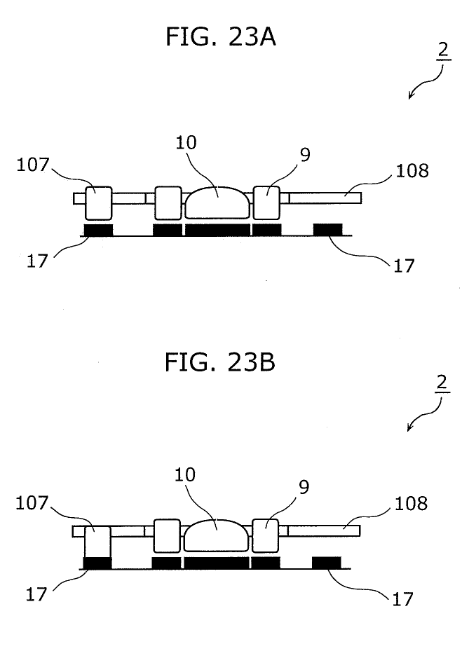

FIGS. 23A and 23B are cross-sectional diagrams showing a structure of the input device 2 in the present embodiment, and are diagrams schematically representing conditions before the wheel button 107 is depressed (FIG. 23A) and after the wheel button 107 is depressed (FIG. 23B). The input device 2 has a plurality of terminals 17 under the wheel unit 108. Moreover, the wheel button 107 is a so-called push switch, and when the wheel unit 108 is rotated and the wheel button 107 is depressed at a predetermined position, the wheel button 107 and the terminal 17 are energized. The input device 2 detects the energization with the terminal 17 when the wheel button 107 has been depressed, as a depression signal.

In this way, the input device 2 may have any mechanism in which both the signal depending on the rotation of the wheel unit 108 and the signal depending on the depression of the wheel button 107 can be outputted, and may also be realized with other structures.

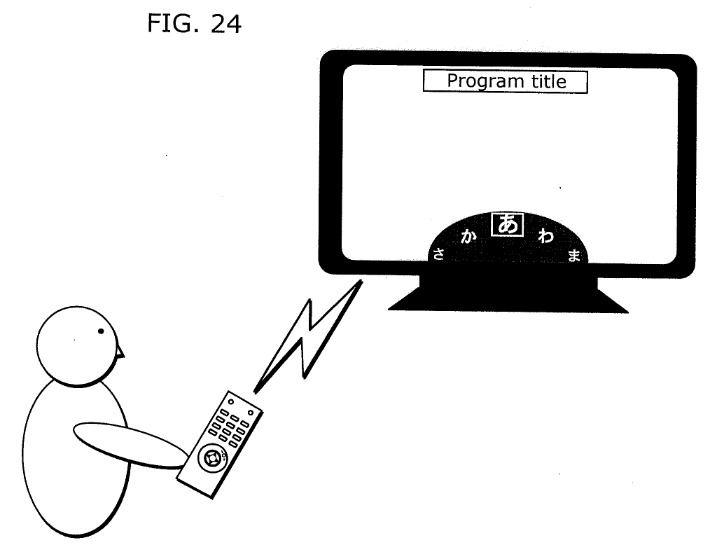

It should be noted that the input device according to the present invention is applicable to various devices such as a remote controller and a gaming machine, which are held in one hand and for which it is necessary to perform the input operation with that one hand. For example, as shown in FIG. 24, when the input device according to the present invention is applied to the remote controller of a television, not only the application is useful for selection of a channel, but also a burden on the user's hand or finger can be reduced when the character input operation is performed for inputting a program name or the like, and moreover, a time required for the operation can be reduced, which thereby enables a comfortable operation. A similar applicability to the remote controller, the gaming machine, and the like as described above also applies to the input device in following third to fifth embodiments.

### THIRD EMBODIMENT

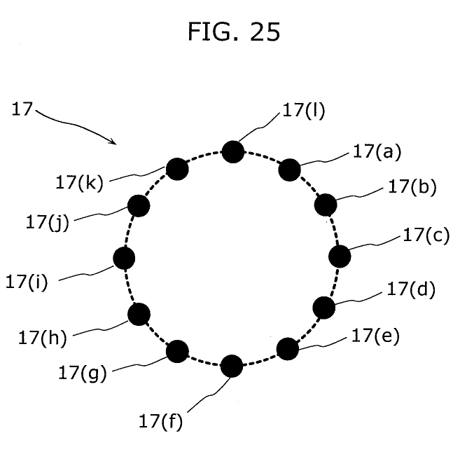

The present embodiment is described by using FIGS. 25 to 35. Note that it is assumed that the mobile terminal 1 in the third embodiment according to the present invention also includes the input device 2 having the rotary body, as described by using FIGS. 21 to 23.

FIG. 25 is a diagram showing the terminals 17 included in the input device 2 in the third embodiment of the present invention. The terminals 17 are arranged under the wheel unit 108, at intervals of 15 degrees on a circular ring centering on the determination key 10, and a circular area made up of 12 terminals 17(a) to 17(l) is formed along the wheel unit 108. The respective terminals 17(a) to 17(l) are assigned with individual and independent terminal IDs (for example, terminal IDs from 1 to 12), and when one terminal in the terminals 17(a) to 17(l) and the wheel button 107 are energized, the input device 2 outputs the ID of the energized terminal along with the depression signal.

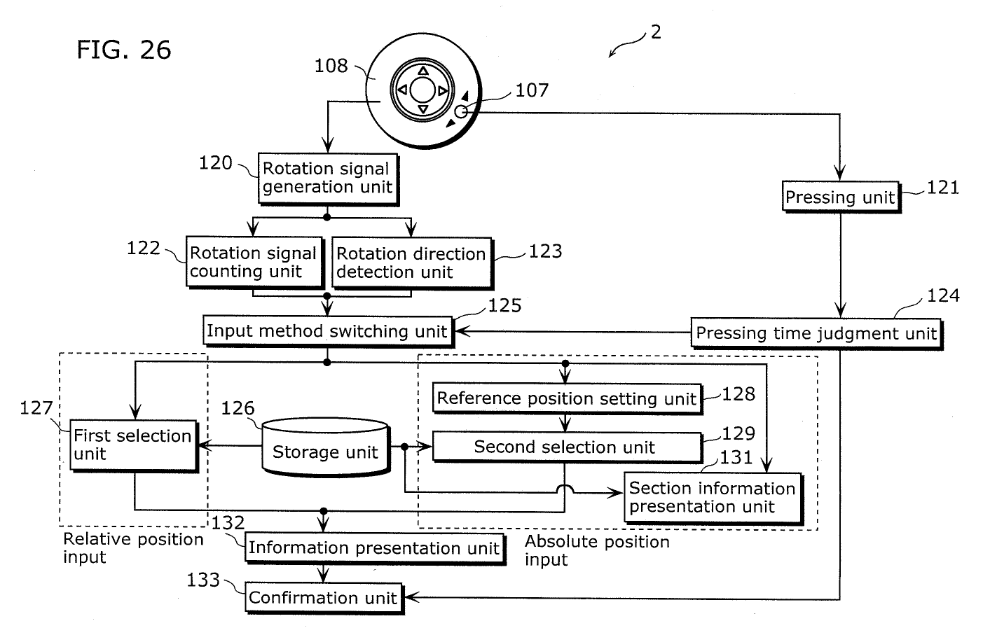

FIG. 26 is a block diagram showing a functional configuration of the input device 2 in the third embodiment of the present invention. This input device 2 functionally includes a rotation signal generation unit 120, a pressing unit 121, a rotation signal counting unit 122, a rotation direction detection unit 123, a pressing time judgment unit 124, an input method switching unit 125, a storage unit 126, a first selection unit 127, a reference position setting unit 128, a second selection unit 129, a section information presentation unit 131, an information presentation unit 132, and a confirmation unit 133.

The rotation signal generation unit 120 is an example of a rotary body according to the present invention, and corresponds to the rotary encoder 11 included in the wheel unit 108.

The pressing unit 121 is an example of an operation unit according to the present invention, and corresponds to the wheel button 107. The wheel button 107 is the depressible push switch, and also functions as a handle when the wheel unit 108 is rotated. Since the wheel button 107 may not be the push switch and may have a structure in which whether pressed or not can be judged, a representation “press” may be used instead of a representation “depress” in the following description.

The rotation signal counting unit 122 and the rotation direction detection unit 123 are an example of an amount of rotation detection unit according to the present invention, and sense a physical amount related to the rotation of the wheel unit 108. Specifically, from an output signal of the rotation signal generation unit 120, a rotation angle and a rotation direction of the wheel unit 108 are identified.

The pressing time judgment unit 124 is an example of a pressing sensing unit according to the present invention, and senses whether or not the pressing unit 121 is being pressed. Specifically, the depression signal of the pressing unit 121 and the energized terminal ID are outputted to either the input method switching unit 125 or the confirmation unit 133, by judging a length of a pressing time of the pressing unit 121. In other words, when the pressing unit 121 has been pressed for equal to or more than a threshold time for switching (for example, one second or more), a pressing signal and the energized terminal ID are outputted to the input method switching unit 125. On the other hand, when the pressing unit 121 has been pressed only for equal to or less than the threshold time for switching, the pressing signal and the energized terminal ID are outputted to the confirmation unit 133.

It should be noted that, in the following description, to press for equal to or more than the threshold time for switching may be referred to as “long-press”.

The input method switching unit 125 is an example of a switching unit according to the present invention, and switches whether the rotation angle and the rotation direction of the wheel unit 108 are outputted to the first selection unit 127 or the second selection unit 129. Specifically, when the pressing signal has been received from the pressing time judgment unit 124 in a state in which the first selection unit 127 is enabled, the rotation angle and the rotation direction of the wheel unit 108 are switched to be outputted to the reference position setting unit 128 and the section information presentation unit 131. On the other hand, when the pressing signal has been received from the pressing time judgment unit 124 in a state in which the second selection unit 129 is enabled, the rotation angle and the rotation direction of the wheel unit 108 are switched to be outputted to the first selection unit 127. Here, the rotation angle of the wheel unit 108 has been identified by the rotation signal counting unit 122, and the rotation direction of the wheel unit 108 has been identified by the rotation direction detection unit 123.

The storage unit 126 is an example of an information set storage unit according to the present invention, and stores an information set which is a collection of ranked information. In the storage unit 126, as described later, character information 30 has been stored. This storage unit 126 is specifically a ROM (Read Only Memory), or the RAM (Random Access Memory), or the hard disk, or the like, and the information set is specifically a collection of the function information, the character information, and the like included in the mobile terminal 1.

The first selection unit 127 is an example of a first selection unit according to the present invention, and selects information from among the information set stored in the storage unit 126. Specifically, information corresponding to the rotation angle and the rotation direction of the wheel unit 108 is read from the storage unit 126, however, details are described later.

The reference position setting unit 128 is an example of a reference position setting unit according to the present invention, and changes the rotation angle and the rotation direction of the wheel unit 108 to initial values corresponding to an amount of rotation of 0 when the switching from the first selection unit 127 to the second selection unit 129 is performed, and thereby sets a position of the pressing unit 121 at a time point when the switching has been performed, as a reference position. Specifically, when the switching from the first selection unit 127 to the second selection unit 129 is performed, the rotation angle and the rotation direction of the wheel unit 108 are reset to 0, and outputted to the second selection unit 129. Although the reference position may be set at the time point of the switching in this way, the reference position may be set at the time of starting a character input mode which is closest to the switching.

The second selection unit 129 is an example of a second selection unit according to the present invention, and selects the information from among the information set stored in the storage unit 126. Specifically, the information corresponding to the rotation angle and the rotation direction of the wheel unit 108 is read from the storage unit 126, however, details are described later.

It should be noted that the selection unit in the present invention is a generic name indicating any one of, or both the first selection unit 127 and the second selection unit 129 described above.

The section information presentation unit 131 is an LED or the like which presents a predetermined information set including the information which is selected by the second selection unit 129, around the wheel unit 108. “A predetermined information set including the information which is selected by the second selection unit 129” described here means section information. Meanings of “section” and “section information” are described later.

The information presentation unit 132 is a liquid crystal display or the like which presents the information selected by the first selection unit 127 or the second selection unit 129. The user presses the pressing unit 121 when desired information is being selected in the information being presented on the information presentation unit 132.

When this pressing time is equal to or less than the threshold time for switching, the pressing time judgment unit 124 outputs the pressing signal to the confirmation unit 133.

The confirmation unit 133 is an example of a confirmation unit according to the present invention, and confirms information being selected, as the input information, when it is sensed by the pressing time judgment unit 124 that the pressing unit 121 has been pressed. “Information being selected” means the information being selected by the first selection unit 127 or the second selection unit 129.

It should be noted that, it is desirable that the rotation signal counting unit 122, the rotation direction detection unit 123, the pressing time judgment unit 124, the input method switching unit 125, the first selection unit 127, the reference position setting unit 128, the second selection unit 129, and the confirmation unit 133 are realized with software, although may be realized with other units. Moreover, in addition to units which visually present the information with the liquid crystal display or the like, the information presentation unit 26 and the section information presentation unit 131 may be units which auditorily present the information with speech or the like, or may be units which present the information both visually and auditorily.

Hereinafter, in the present embodiment, it is assumed that an input method in the case where the first selection unit 127 reads the information from the storage unit 126 and presents the information on the information presentation unit 132 is referred to as “relative position input method”, and an input method in the case where the second selection unit 129 reads the information from the storage unit 126 and presents the information on the information presentation unit 132 is referred to as “absolute position input method”.

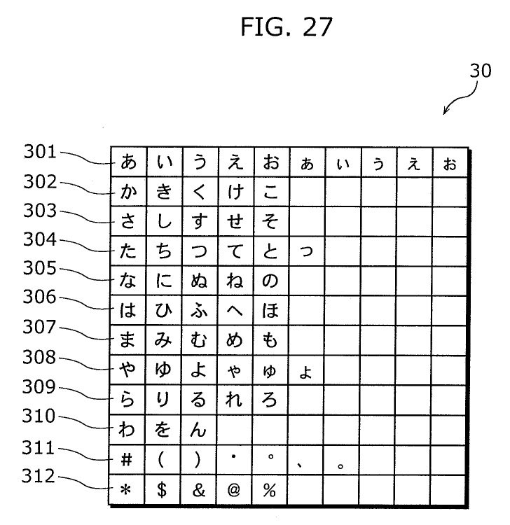

FIG. 27 is an example of the character information 30 included in the storage unit 126 included in the input device 2 in the present embodiment. The character information 30 is composed of 50 syllables of the hiragana, and the signs, and is grouped into line information 301 to 312.

The information presentation unit 132 presents at least some of the line information 301 to 312, as selected target information, to the user.

The first selection unit 127 or the second selection unit 129 selects predetermined line information from among the selected target information, based on the rotation angle and the rotation direction of the wheel unit 108. When confirmation of selection of a desired line from the user has been accepted (for example, when the depression of the wheel button 107 is accepted while “ [symbol] (ha)” line 306 is being selected), the confirmation unit 133 confirms the selected line (“ [symbol] (ha)” line), and the information presentation unit 132 presents at least some of character information set (in this case, “ [symbol] (ha)”, “ [symbol] (hi)”, “ [symbol] (fu)”, “ [symbol] (he)”, and “ [symbol] (ho)”) constituting the confirmed line, as the selected target information. Subsequently, when the user rotates the wheel unit 108, the physical amount related to this rotation is identified by the rotation signal counting unit 122 and the rotation direction detection unit 123. Thereby, depending on the physical amount related to this rotation, a desired character (for example, “ [symbol] (fu)”) is selected by the first selection unit 127 or the second selection unit 129. When the wheel button 107 is further depressed in that state, the character being selected (“ [symbol] (fu)”) is confirmed as an input character by the confirmation unit 133. It should be noted that, after this, the state becomes a state in which the line information can be selected again.

Here, a character information set representing lines of the 50 syllables of the hiragana (“ [symbol] (a)”, “ [symbol] (ka)”, “ [symbol] (sa)”, “ [symbol] (ta)”, “ [symbol] (na)”, and the like) corresponds to “first information set” of the present invention. Moreover, individual pieces of information constituting this character information set correspond to “first unit information” of the present invention. Moreover, a character information set constituting the lines of the 50 syllables of the hiragana (for example, “ [symbol] (a)”, “ [symbol] (i)”, “ [symbol] (u)”, “ [symbol] (e)”, and “ [symbol] (o)” constituting “ [symbol] (a)” line, and “ [symbol] (ka)”, “ [symbol] (ki)”, “<(ku)”, “ [symbol] (ke)”, and “ [symbol] (ko)” constituting “ [symbol] (ka)” line) corresponds to “second information set” of the present invention. Moreover, individual pieces of information constituting this character information set correspond to “second unit information” of the present invention.

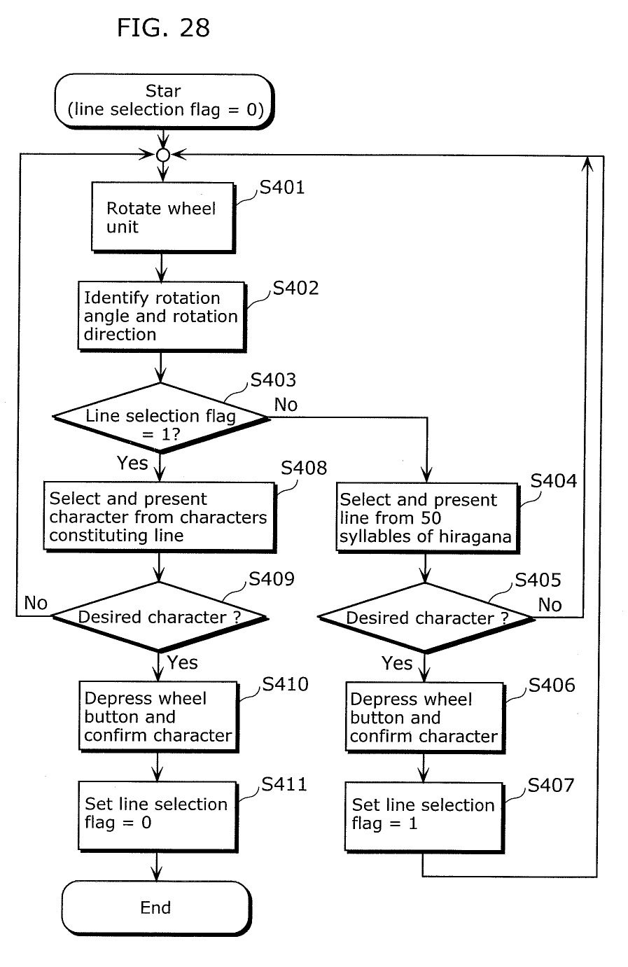

FIG. 28 is a flowchart showing a procedure when a character is inputted according to the relative position input method by using the mobile terminal 1 including the input device 2 in the present embodiment. Specifically, a series of flows until the first selection unit 127 selects desired unit information based on the rotation angle and the rotation direction of the wheel unit 108, and the confirmation unit 133 confirms the selection with the depression of the wheel button 107 is shown.

First, since the wheel unit 108 is rotated by the user (S401), the wheel unit 108 outputs a rotation signal shown in FIG. 22B. The rotation signal counting unit 122 and the rotation direction detection unit 123 identify the rotation angle and the rotation direction of the wheel unit 108 from this rotation signal (S402). At this time, based on the rotation angle and the rotation direction of the wheel unit 108, when the line selection flag included within the input device 2 is “0” (S403: No), the first selection unit 127 selects information representing a predetermined line from among the character information set representing the lines of the 50 syllables of the hiragana (S404), and when the line selection flag is “1” (S403: Yes), the first selection unit 127 selects predetermined character information from character information constituting the line being selected (S408). When the user hopes to confirm the input for the line information or the character information being selected by the first selection unit 127 (S405: Yes, or S409: Yes), the user depresses the wheel button 107, and when the user hopes to select another line information or character, the user rotates the wheel unit 108 again (S405: No, or S409: No). With the depression of the wheel button 107, the confirmation unit 133 confirms the character information representing the selected line or confirms the input of the character information constituting the line (S406, S410). The input device 2 sets the line selection flag included therein to “1” when the selection of the line information has been confirmed (S407), and sets the line selection flag to “0” when the selection of the character constituting the line has been confirmed (S411). According to such a series of flows, the input of one character is confirmed. After the input of one character has been confirmed, when the wheel unit 108 has been further rotated by the user (S401), the line selection flag is set to “0”. Then, the first selection unit 127 selects the predetermined character information from among the above described line information (S404).

It should be noted that, in the present embodiment, although it is assumed that the line selection flag included within the input device 2 is composed of software, the line selection flag may be composed of hardware. For example, the wheel button 107 may be composed of a so-called tact switch or the like, and the line selection flag may be set to “1” when the wheel button 107 is in the state of being electrically energized with the circuit included in the input operation device 2, and the line selection flag may be set to “0” in the insulating state.

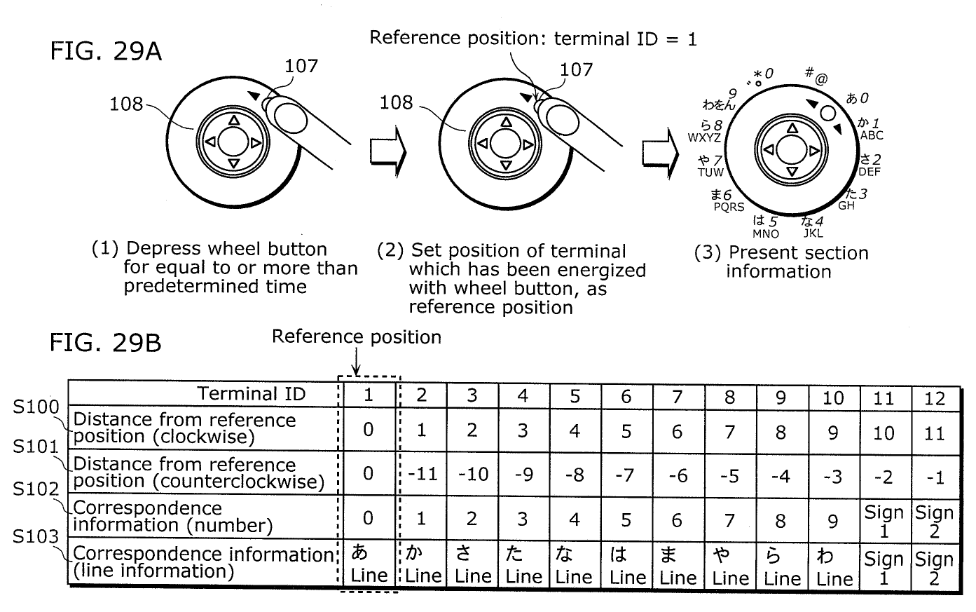

FIG. 29 is a diagram showing a procedure when the input method is switched from the relative position input to the absolute position input by using the input device 2 in the third embodiment of to the present invention. Specifically, FIG. 29A is a diagram showing an operational procedure until the section information is presented by the section information presentation unit 131, and FIG. 29B is a diagram showing a correspondence between character-related information stored in the storage unit 126 and sections.

When the pressing time judgment unit 124 has sensed that the wheel button 107 has been depressed for equal to or more than the threshold time for switching, the pressing time judgment unit 124 outputs the terminal ID of the terminal 17 which has been energized with the wheel button 107, along with the depression signal, to the input method switching unit 125. Here, as shown in (1) and (2) of FIG. 29A, since a case where the wheel button 107 has been long-pressed at a position corresponding to the terminal 17(a) with the terminal ID of 1 is assumed, the terminal ID “1” is outputted from the pressing time judgment unit 124 to the input method switching unit 125. At this time, when the relative position input method has been enabled, the input method switching unit 125 switches the input method to the absolute position input method. Thereby, the reference position setting unit 128 sets a position of the wheel button 107 at this time as a second reference position by resetting the rotation angle and the rotation direction of the wheel unit 108 to 0.

As a result, for the terminal 17(a) with the terminal ID of 1, as shown in S100 and S101 of FIG. 29B, a distance from the second reference position becomes “0” which is an initial value, both when the wheel button 107 is clockwise and when the wheel button 107 is counterclockwise, and as shown in S102 of FIG. 29B, correspondence information (number) becomes the number “0”, and as shown in S103 of FIG. 29B, correspondence information (line information) becomes “ [symbol] (a)-line” of the hiragana. Then, as the terminal ID becomes larger like “2, 3, 4, . . . , 12”, the distance from the second reference position (clockwise) becomes “1, 2, 3, . . . , 11”, the distance from the second reference position (counterclockwise) becomes “−11, −10, −9, . . . , −1”, the correspondence information (number) becomes “1, 2, 3, . . . , sign 2”, and the correspondence information (line information) becomes “ [symbol] (ka)-line, [symbol] (sa)-line, [symbol] (ta)-line, . . . , sign 2”. It should be noted that the distance from the second reference position can be calculated based on the reference position set by the reference position setting unit 128, and the rotation angle and the rotation direction of the wheel unit 108.

As shown in (3) of FIG. 29A, the section information presentation unit 131 presents the section information which has been associated with each section by the second selection unit 129, around the wheel unit 108, by lighting the LED. “Section” means one unit area when the wheel unit 108 has been divided into 12 in a manner corresponding to the 12 terminals 17, and “section information” means character-related information which has been associated with each section by the second selection unit 129, specifically, numbers “0”, “1”, “2”, “3”, “4”, “5”, “6”, “7”, “8”, “9”, “sign 1”, and “sign 2”, and the hiragana “ [symbol] (a)-line”, “ [symbol] (ka)-line”, “ [symbol] (sa)-line”, “ [symbol] (ta)-line”, “ [symbol] (na)-line”, “ [symbol] (ha)-line”, “ [symbol] (ma)-line”, “ [symbol] (ya)-line”, “ [symbol] (ra)-line”, “ [symbol] (wa)-line”, “sign 1”, and “sign 2”. When the section information is presented around the wheel unit 108 in this way, it becomes possible for the user to perform the input operation while checking character-related information which is being selected by the user himself, with a positional relationship between the mobile terminal 100 and the wheel button 107 as a clue. It should be noted that the above described “sign 1” and “sign 2” are specifically a set of signs such as ( ) [symbol] , ∘ “ # * ! ? + ̂ ; : which are used in the character input and the like. Here, the set of the signs is classified into two groups depending on intended uses and the like.

Here, when the user rotates the wheel unit 108, the second selection unit 129 moves the rank depending on a distance from the reference position of the wheel button 107, with second reference information in the character information 30 stored in the storage unit 126 as a reference point, and thereby selects the information from among the character information 30. The second reference information is information which is selected when the amount of rotation (rotation angle) of the wheel unit 108 is 0, and specifically means the number “0” and “ [symbol] (a)-line” of the hiragana. Therefore, when the wheel unit 108 has rotated clockwise for one unit (15 degrees) in a state in which the character input mode has been set, the second selection unit 129 moves the rank by one rank in a forward direction of “ [symbol] (a) [symbol] (ka) [symbol] (sa) [symbol] (ta) [symbol] (na)” with “ [symbol] (a)-line” in the character information 30 as the reference point, and thereby selects “ [symbol] (ka)-line” from among the character information 30. Of course, the position of the wheel button 107 at this time has become a position corresponding to the terminal 17(b) with the terminal ID of 2.

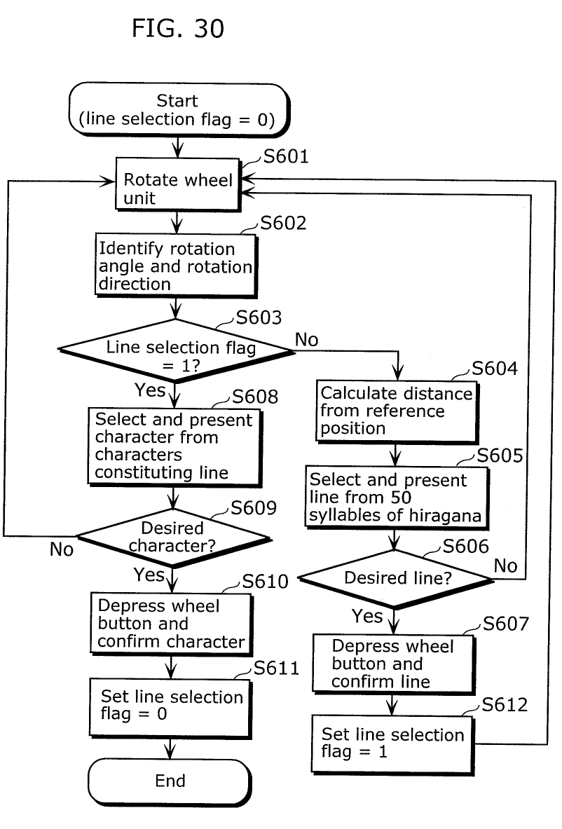

FIG. 30 is a flowchart showing a procedure for inputting a character according to the absolute position input method by using the mobile terminal 1 including the input device 2 in the third embodiment of the present invention. Here, a series of flows until the second selection unit 129 selects the information from the storage unit 126 based on the rotation angle and the rotation direction of the wheel unit 108, and an information confirmation unit 32 confirms the selection with the pressing on the wheel button 107 is described. Here, it is assumed that the second reference position has been already set according to the procedure described by using FIG. 29.

Since the user rotates the wheel unit 108 (S601), the wheel unit 108 outputs the rotation signal. The rotation signal counting unit 122 and the rotation direction detection unit 123 identify the rotation angle and the rotation direction of the wheel unit 108 from this rotation signal (S602). At this time, when the line selection flag which has been internally included in the input device 2 is 0 (S603: No), the second selection unit 129 calculates the distance from the second reference position, based on the second reference position set by the reference position setting unit 128, and the rotation angle and the rotation direction of the wheel unit 108 (S604). Subsequently, from among the character information 30, line information corresponding to the distance from the second reference position is selected (S605). On the other hand, when the line selection flag is 1 (S603: Yes), from among characters constituting the line information being selected, a character corresponding to the rotation angle and the rotation direction of the wheel unit 108 is selected (S608).

When desired line information or character is being selected (S606: Yes, or S609: Yes), the user depresses the wheel button 107 and thereby confirms the selection of the line information or character being selected (S607, S610). On the other hand, when the desired line information or character is not being selected (S606: No, or S609: No), the wheel unit 108 is rotated again, and thereby another line information or character is selected (S601). The input device 2 sets the line selection flag to 1 when the selection of the line information has been confirmed (S612), and sets the line selection flag to 0 when the selection of the character has been confirmed (S611). According to such a series of flows, the input of one character is confirmed. When the user has rotated the wheel unit 108 again for inputting, in continuation, another character (S601), since the line selection flag has been set to 0, it is possible to select the predetermined line information from among the character information 30 (S605).

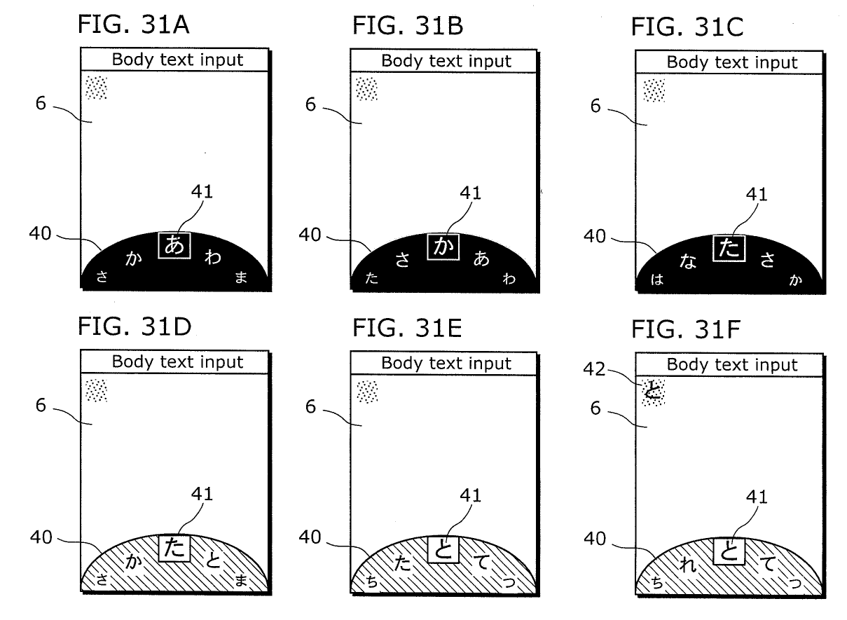

FIGS. 31A to 31F are diagrams showing the information which is displayed on the display unit 6 when the character input operation is being performed in the relative position input method by using the mobile terminal 1 including the input device 2 in the third embodiment of the present invention. In other words, a series of flows is described in which the information presentation unit 132 presents the information selected by the first selection unit 127 on the display unit 6.

When the user performs the character input operation, the character being selected by the first selection unit 127 (selected character) is highlighted within a frame of the fixed frame 41, and is being displayed in a font larger than other characters. The Information presentation unit 132 presents the generally semicircular-shaped wheel GUI (Graphical User Interface) 50 on the display unit 6, and arranges the selected character and information adjacent thereto on this wheel GUI 40 in such a manner in which a circular arc is drawn. Since the selected character is highlighted and displayed in the font larger than the adjacent information in this way, the user can clearly comprehend the selected character. Moreover, since the selected character is displayed at a fixed position, movement of a line of sight of the user during the operation decreases, and it becomes easy to comprehend the selected character. Furthermore, since not only the selected character but also the characters next thereto are displayed, the user can also check the characters previous and next to the selected character. In addition, on the wheel GUI 40, only some of the line information 401 to 412 in the character information 30 stored in the storage unit 126 are displayed. Since the information to be displayed is reduced in this way, it becomes easier for the user to find target line information. When the wheel unit 108 is rotated, the line information to be displayed on the wheel GUI 40 is interchanged according to the rotation, and as a result, all line information can be selected. Also when the characters constituting each piece of the line information 401 to 412 are displayed, since a similar display method has been employed, a similar effect can be obtained.

Hereinafter, the operation when “ [symbol] (to)” of the hiragana is inputted is described by using FIGS. 31A to 31F.

First, as shown in FIG. 31A, in the characters constituting each piece of the line information in the character information 30, beginning characters (“ [symbol] (a)”, “ [symbol] (ka)”, “ [symbol] (sa)”, and “ [symbol] (ma)”, “ [symbol] (wa)”) are displayed on the wheel GUI 40. Here, since a case where “ [symbol] (a)-line” is a first reference information is assumed, a status in which the character “ [symbol] (a)” is being selected is shown.

At this time, as shown in FIGS. 31B and 31C, when the user rotates the wheel unit 108 clockwise, the lines are selected in an order of “ [symbol] (ka)”, “ [symbol] (sa)”, and “ [symbol] (ta)”, and highlighted and displayed in the order in the fixed frame 41. When the user depresses the wheel button 107 while “ [symbol] (ta)” line is being selected, the confirmation unit 133 confirms the selection of “ [symbol] (ta)” line, and the respective characters “ [symbol] (ta)”, “ [symbol] (chi)”, “ [symbol] (tsu)”, “ [symbol] (te)”, and “ [symbol] (to)” constituting “ [symbol] (ta)” line are displayed on the wheel GUI 40. At this time, as shown in FIG. 31D, the information presentation unit 132 changes the color of the wheel GUI 40. Thereby, the user can clearly comprehend whether the user is selecting the line information in the character information 30 or selecting the character constituting the line information.

Subsequently, as shown in FIGS. 31D and 31E, when the user rotates the wheel unit 108 counterclockwise, the characters are selected in an order of “ [symbol] (ta)” and “ [symbol] (to)”, and highlighted and displayed in the order in the fixed frame 41. When the user depresses the wheel button 107 while the character “ [symbol] (to)” is being selected, the information confirmation unit 32 confirms the selection of the character “ [symbol] (to)”, and the character “ [symbol] (to)” is displayed on the input screen 42. According to the above operation, the user can easily input the desired character while seeing the display unit 6, without feeling the operational burden.

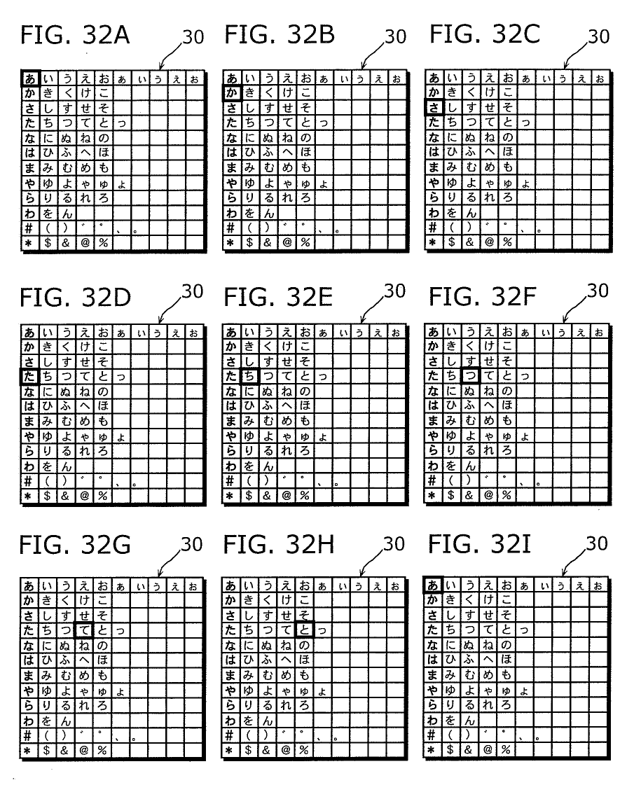

FIGS. 32A to 32I are diagrams showing a transition of a character which is selected from among the character information 30 when a character is inputted according to the relative position input method. Here, a case where the character “ [symbol] (to)” is inputted is illustrated and described.

First, as shown in FIG. 32A, when the user rotates the wheel unit 108 clockwise for three units in a state in which “ [symbol] (a)” line which is the first reference information has been selected, as shown in FIGS. 32B, 32C, and 32D, the lines are selected in the order of “ [symbol] (ka)”, “ [symbol] (sa)”, and “ [symbol] (ta)”. When the user presses the wheel button 107 in a state in which “ [symbol] (ta)” line has been selected in this way, the state becomes a state in which the respective characters “ [symbol] (ta)”, “ [symbol] (chi)”, “ [symbol] (tsu)”, “ [symbol] (te)”, and “ [symbol] (to)” constituting “ [symbol] (ta)” line can be selected. As shown in FIGS. 32E, 32F, 32G, and 32H, when the user rotates the wheel unit 108 clockwise for four units in this state, the characters are selected in an order of “ [symbol] (chi)”, “ [symbol] (tsu)”, “ [symbol] (te)”, and “ [symbol] (to)”. When the user presses the wheel button 107 in this state, the character “ [symbol] (to)” is confirmed as the input information. Here, as shown in FIG. 32I, in the relative position input method, “ [symbol] (a)” line which is the first reference information is selected, and subsequently, the information is selected from among the character information 30 in the same manner. In other words, when the input information is confirmed, “ [symbol] (a)” line which is the first reference information becomes the reference point, and when the wheel unit 108 rotates again, the rank moves depending on the amount of rotation.

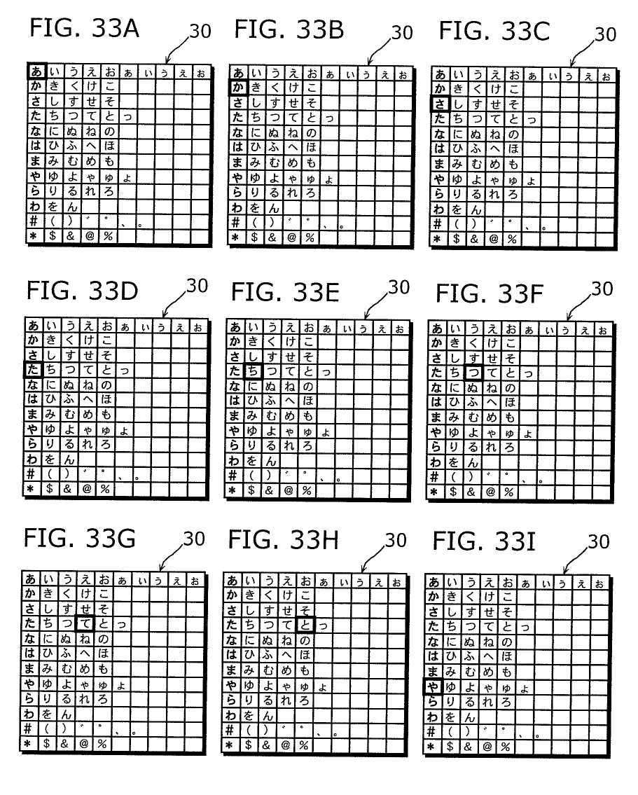

FIGS. 33A to 33I are diagrams showing a transition of a character which is selected from among the character information 30 when a character is inputted according to the absolute position input method. Also here, the case where the character “ [symbol] (to)” is inputted is illustrated and described.

The case is similar to the case of the relative position input method, until the character “ [symbol] (to)” is confirmed as the input information. In other words, as shown in FIG. 33A, when the user rotates the wheel unit 108 clockwise for three units in a state in which “ [symbol] (a)” line which is the second reference information has been selected, as shown in FIGS. 33B, 33C, and 33D, the lines are selected in the order of “ [symbol] (ka)”, “ [symbol] (sa)”, and “ [symbol] (ta)”. When the user presses the wheel button 107 in the state in which “ [symbol] (ta)” line has been selected in this way, the state becomes the state in which the respective characters “ [symbol] (ta)”, “ [symbol] (chi)”, “ [symbol] (tsu)”, “ [symbol] (te)”, and “ [symbol] (to)” constituting “ [symbol] (ta)” line can be selected. As shown in FIGS. 33E, 33F, 33G, and 33H, when the user rotates the wheel unit 108 clockwise for four units in this state, the characters are selected in the order of “ [symbol] (chi)”, “ [symbol] (tsu)”, “ [symbol] (te)”, and “ [symbol] (to)”. When the user presses the wheel button 107 in this state, the character “ [symbol] (to)” is confirmed as the input information. Here, as shown in FIG. 33I, in the absolute position input method, “ [symbol] (ya)” line is selected, and subsequently, the information is selected from among the character information 30 in the same manner. In other words, when the character “ [symbol] (to)” is confirmed as the input information, since the wheel unit 108 at the time has rotated clockwise for seven units from the reference position, “ [symbol] (ya)” line to which the rank has moved for seven units from “ [symbol] (a)” line which is the second reference information is selected.

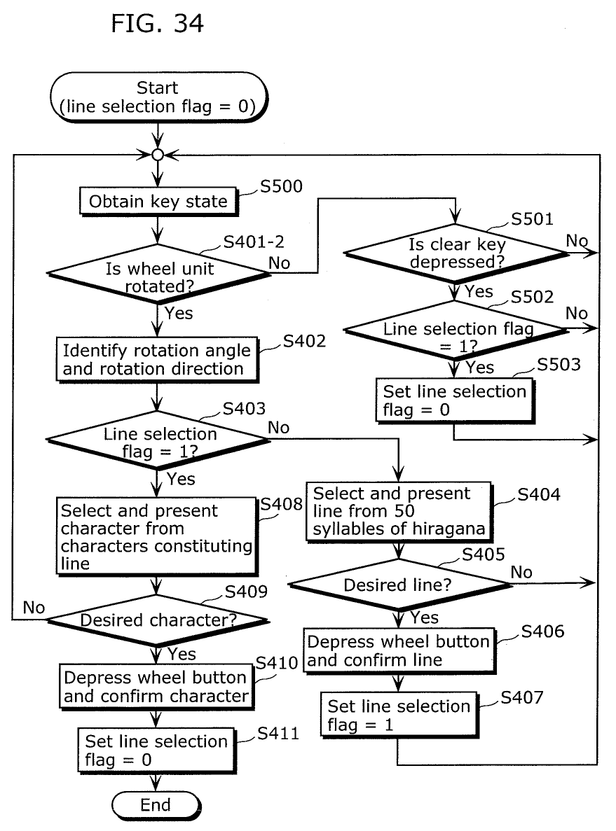

FIG. 34 is a flowchart showing operation content when a clear key which is one of keys constituting the function invocation keys 5 has been depressed while the character input operation is being performed by using the mobile terminal 1 including the input device 2 in the present embodiment. The clear key is a key having a function which executes cancel or deletion of the confirmed function information or character information. When the input device 2 is operated by the user, information on an operated key is obtained (S500). When the above described operation is the rotation of the wheel unit 108 (S401-2: Yes), as described in the above FIG. 28, a process depending on the rotation angle and the rotation direction of the wheel unit 108 is performed. On the other hand, when the clear key of the input device 2 is depressed by the user (S401-2: (No), S501: Yes), in the input device 2, when the line selection flag included therein is “1” (S502: Yes), that is, in the case where character information representing a desired line has been confirmed by the user and one desired character is being selected from a plurality of characters constituting the above described line, the line selection flag is set to be changed to “0” (S503). Thereby, it becomes possible for the user to select and confirm the character information representing the predetermined line again. Thus, even when the user has temporarily and mistakenly confirmed character information representing a line, which is other than the character information representing the desired line, it is possible to easily redo the selection of the character information representing the line again by depressing the clear key.

It should be noted that, in the present embodiment, although the above described function is realized by using the clear key, of course, the above described function may be realized with other keys.

Moreover, in the present embodiment, although only an operation of the clear key in the function invocation keys 5 has been described, operations of other function invocation keys 5 are not particularly defined. To other function invocation keys 5, operations required for the operation of the input device 2 (for example, the telephone call, call ending, a Web browsing function, and the like) may be assigned.

Moreover, other operations of the clear key are not defined in this flowchart. For example, when the clear key has been depressed while the line selection flag is 0 (S502: No), a process such as performing deletion of the character of which the input has been already confirmed may be performed.

Furthermore, in the present embodiment, although when the wheel unit 108 is rotated clockwise, the characters “ [symbol] (ka)”, “ [symbol] (sa)”, and “ [symbol] (ta)” in the character information representing the lines have been selected in the order, of course, it may be assumed that the display is performed as described above when the wheel unit 108 has been rotated counterclockwise.

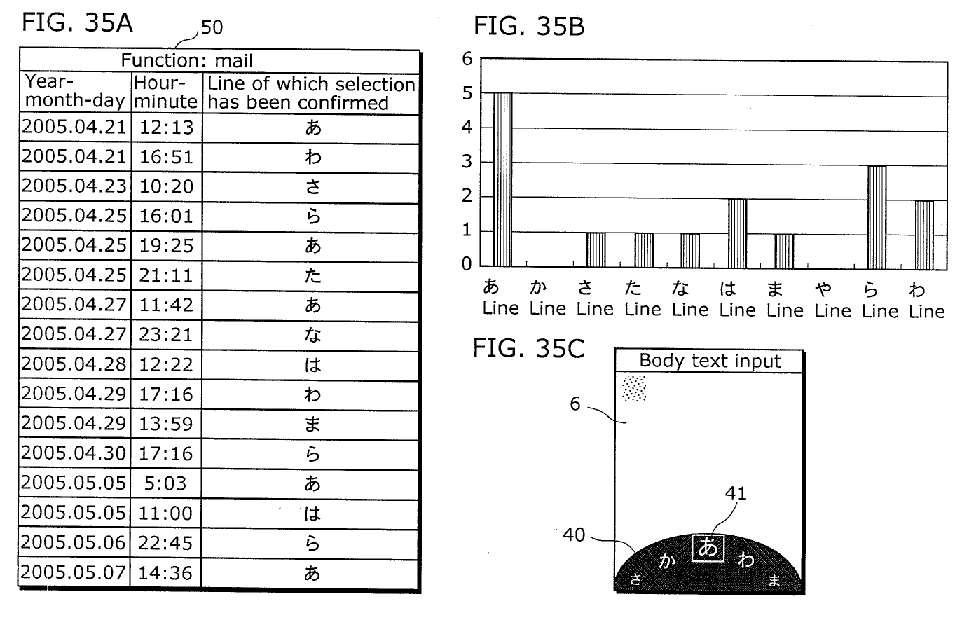

FIGS. 35A to 35C are diagrams for illustrating a process in which a character to be displayed first in the fixed frame 41 when the mail function of the mobile terminal 1 including the input device 2 in the present embodiment has been activated is determined.

FIG. 35A is a diagram schematically representing a list which has stored character information representing a line of which the selection has been confirmed first by the user after the activation of the mail function in past times. A list 50 is stored in the storage unit 126 included in the input device 2, and retains year-month-day and time when the mail function has been activated by the user, and line information of which the selection has been confirmed first after the activation of the mail function. To this list 50, a certain area in the storage unit 126 has been assigned, and after the mail function has been activated, when the selection of the line information has been confirmed first, information is automatically added and old information is deleted.

In FIG. 35B, the character information representing the selected and confirmed lines included in the list 50 in the above described FIG. 35A has been graphed, and FIG. 35C is a diagram representing the display unit 6 immediately after the mail function has been activated by the user. According to FIG. 35B, since it can be seen that a most frequent character information representing the line of which the selection has been confirmed first by the user after the activation of the mail function in past times is “ [symbol] (a)”, as represented in FIG. 35C, it is assumed that the selection unit 25 is selected first when the mail function has been activated by the user, and the character information to be displayed in the fixed frame 41 by the information presentation unit 26 is “ [symbol] (a)”. According to such a process, when the user activates the mail function, the character information representing the line which is frequently selected is automatically selected by the selection unit 25 and displayed in the fixed frame 41, and thereby an input time can be reduced.

It should be noted that although the list 50 in the present embodiment has been described as the list in the mail function, of course, the above described list may also be included in other functions. Moreover, when a different list is included for each function of the mobile terminal 1, it is possible to attempt to reduce the input time also in the case where character information representing a line to be selected first is different for each function. Moreover, although the list 50 in the present embodiment stores an activation year-month-day, an activation time, and selected line information, of course, other information may be stored, or information other than the character information representing the selected and confirmed lines may not be stored.

As described above, according to the mobile terminal 1 including the input device 2 in the third embodiment of the present invention, it becomes possible for the user to input the predetermined information such as the character, only with the rotation of the wheel unit 108 and the depression of the wheel button 107, and it becomes possible to reduce a burden when the finger is moved to a key assigned with the target information.

Moreover, it is possible to switch between the relative position input method suitable for inputting the information while seeing the display unit 6, and the absolute position input method suitable for inputting the information without seeing the display unit 6, by a simple operation of long-pressing the wheel button 107. Thereby, it becomes possible to provide an input device with good operability, which can flexibly respond to a status in which the user is using the input device or the user's preferences.

When such a configuration has been set, it is possible to realize a usage depending on a status of use or the preferences of the user, in which the relative position input method with a high input speed is normally used and is switched to the absolute position input method in a time of emergency such as a time when the display is broken, and the like.

In other words, when the character-related information is inputted according to the relative position input method, since the information being selected by the first selection unit 127 is displayed on the display unit 6, it is not necessary for the user to see the hand. Thus, there is no delay in the input time due to a time of searching information which is desired to be inputted while seeing the hand, and the input time can be reduced.

On the other hand, when the character-related information is inputted according to the absolute position input method, since the user can input the character-related information with the positional relationship between the mobile terminal 1 and the wheel button 107 as the clue, it becomes possible to input a telephone number and the like for using the telephone call function of the mobile terminal, in a state in which the display unit 6 is not seen. In other words, even when the display unit 6 has been broken due to a disaster such as an earthquake, it becomes possible to make an emergency call.

Moreover, since the clear key is provided, when the character constituting the predetermined line is being selected, it becomes possible for the user to redo the selection of the character information representing the line again. Thus, even when the user has temporarily and mistakenly selected the character information representing the line, which is other than the character information representing the desired line, it is possible to recover from an error with a small operational burden and a short operation time.

Furthermore, since the character being selected by the first selection unit 127 or the second selection unit 30 (selected character) is highlighted and displayed in a large font within the frame of the fixed frame 41 on the wheel GUI 40 by the information presentation unit 132, the movement of the line of sight of the user during the operation can be decreased, and the user can clearly comprehend which character is being selected.

Furthermore, since not only character information representing a target line to be selected but also character information representing the selected target information next thereto is displayed, the user can also check the character information as the selected target information previous and next to the character information being selected.

Moreover, in the present embodiment, “ [symbol] (a)” which is character information representing a beginning line of the 50 syllables of the hiragana and “ [symbol] (wa)” which is character information representing an end line are displayed in a side-by-side manner. Since such display requires only few wheel operations even when “ [symbol] (wa)” line which is the end line is desired to be selected while “ [symbol] (a)” line which is the beginning line is being selected, the burden on the user can be reduced, and the operation time can also be reduced.

Furthermore, the information presentation unit 26 changes the color of the wheel GUI 40 being displayed on the display unit 6 between in a case where the user is caused to select the character information representing the line and in a case where the user is caused to select the character information constituting the line. Thereby, the user can clearly comprehend whether the user is selecting the character information representing the line in the character information 30 or selecting the character information constituting the line.

Moreover, when a predetermined function has been activated, based on a history of the line of which the selection has been confirmed by the user in past times, the mobile terminal 1 including the input device 2 in the present embodiment determines the character information representing the line to be displayed first in the fixed frame 41. Thus, when the user activates the above described predetermined function, the line information which is frequently selected is displayed in a state of having been automatically selected, in the fixed frame 41, and thereby the input time can be reduced.

With the above described effects, according to the input device 2 according to the present embodiment, the burden on the user's hand or finger is reduced and the time required for the operation is also reduced, which enables the comfortable operation.

It should be noted that, in the present embodiment, the wheel unit 108 is composed of the rotary encoder, which, however, may be another configuration when the configuration can output the rotation angle and the rotation direction of the wheel unit 108. In this case, it is desirable that the wheel unit 108 is composed of a member which can be operated by a rotary torque not imposing the burden on the user, and that a configuration in which the operation unit is not degraded by abrasion due to a long term use is employed.

Moreover, in the present embodiment, although it is assumed that the information is displayed on the display unit 6 with the GUI, an information presentation mode is not limited thereto. In other words, with a configuration in which the information being selected is not only displayed with the GUI but also presented with the speech by the information presentation unit 132, it becomes possible to provide an input device which can also be used by a user having a difficulty in comprehending the information being selected, only with visual information, such as a visually-impaired person or a person with weak eyesight.

Moreover, in the present embodiment, although it has been described that the information is displayed on the display unit 6 only in the case of the relative position input method, the information may be similarly displayed on the display unit 6 also in the case of the absolute position input method.

Moreover, in the present embodiment, although it has been assumed that the line information from “ [symbol] (a)” line to “ [symbol] (wa)” line is selected and confirmed first and subsequently the character constituting each piece of the line information (column information) is selected and confirmed, a similar effect can also be obtained when the column information is selected and confirmed first and subsequently the character constituting each piece of the column information (line information) is selected and confirmed.

Moreover, in the present embodiment, although it has been assumed that the pressing time judgment unit 124 outputs the pressing signal to the input method switching unit 125 when the pressing unit 121 has been pressed for one second or more, the above described time may not be necessarily one second. In other words, the time may be any time in which the user can clearly distinguish a normal pressing from a pressing for switching the input method.

Furthermore, in the present embodiment, although it has been assumed that when the pressing time judgment unit 124 judges that the wheel button 107 has been long-pressed, the input method switching unit 125 performs the switching between the relative input method and the absolute input method, it may be assumed that the input method is switched with long-pressing of another button other than the long-pressing of the wheel button 107. Specifically, the input method may be switched by using a button of other than the wheel unit 108 included in the mobile terminal 1. In this case, it may be judged whether or not the button which is used for the above described switching is being depressed. Moreover, the input method may be switched by using a slide switch instead of the above described button.

Moreover, in the present embodiment, although the first and second reference information has been the number “0” or [symbol] (a)-line of the hiragana, of course, other information may be the reference information. Although a case where alphabet is inputted has not been referred to, in that case, it is desirable that “A” is the reference information.

Moreover, in the present embodiment, although the position at which the wheel button 107 has been long-pressed has been the reference position, the present invention is not limited thereto. In other words, it is also possible to set a specific position as the reference position when the wheel button 107 is long-pressed at any position. For example, when it is assumed that the number “0” or [symbol] (a)-line of the hiragana is always associated with the terminal 17(a) with the terminal ID of 1, since the section information to be presented around the wheel unit 108 is always constant, the absolute position input with further good operability becomes possible. When the section information to be presented around the wheel unit 108 is always constant in this way, the terminal ID is not necessarily required. Of course, even in the case where the position at which the wheel button 107 has been long-pressed is set as the reference position, when a mode in which the section information is not presented around the wheel unit 108 is employed, the terminal ID is not necessarily required.

Furthermore, in the present embodiment, although the information presentation unit 132 displays the character information adjacent to each piece of the information when either the character information representing the line in the character information 30 or each piece of the character information constituting the line is displayed, such display may not be necessarily performed. For example, an adjacent character may not be displayed when the character information representing the line is displayed, and the adjacent character may be displayed only when each character constituting the line is displayed, and vice versa. Also with such display, an operator can clearly comprehend whether the operator is selecting the character information representing the line in the character information 30 or selecting the character information constituting the line, at a glance.

Moreover, in the present embodiment, although it is assumed that the information presentation unit 132 presents the character being selected, in the font larger than other characters, it may be assumed that the character being selected is presented in a color different from other characters, and the display may have any mode in which the information being selected can be distinguished from other information.

Moreover, although the mobile terminal 1 including the input device 2 in the present embodiment has been configured so that when a predetermined function has been activated, a character to be selected first is determined based on the beginning character constituting the line information of which the selection has been confirmed first after the user has activated the above described predetermined function in past times, another method may be possible when the method determines the character to be displayed, based on a history of the character input in past times by the user. For example, the character information representing the line to which the character, of which the selection has been confirmed first after the user has activated the above described predetermined function in past times, belongs may be stored, and the beginning character of the line information of which a largest number of pieces have been stored may be selected first therefrom.

### FOURTH EMBODIMENT

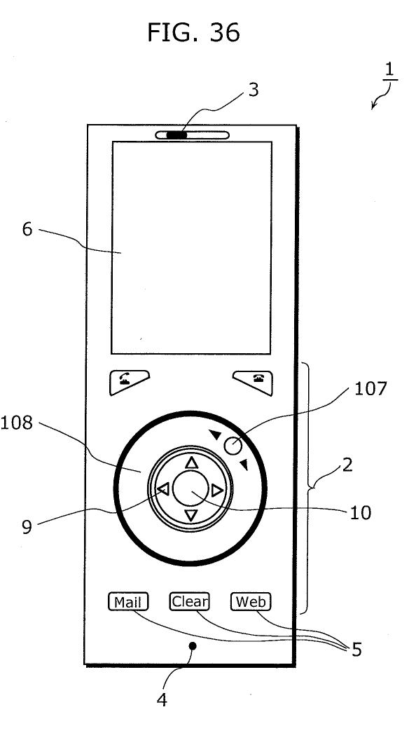

The fourth embodiment is described with a focus on different points from the third embodiment, by using FIGS. 36 to 44. It should be noted that the same reference characters are used for parts similar to the third embodiment, and descriptions thereof are omitted.

FIG. 36 is an external view of the mobile terminal 1 including the input device 2 in the fourth embodiment of the present invention. Since an external appearance of this mobile terminal 1 is similar to the third embodiment, a description thereof is omitted.

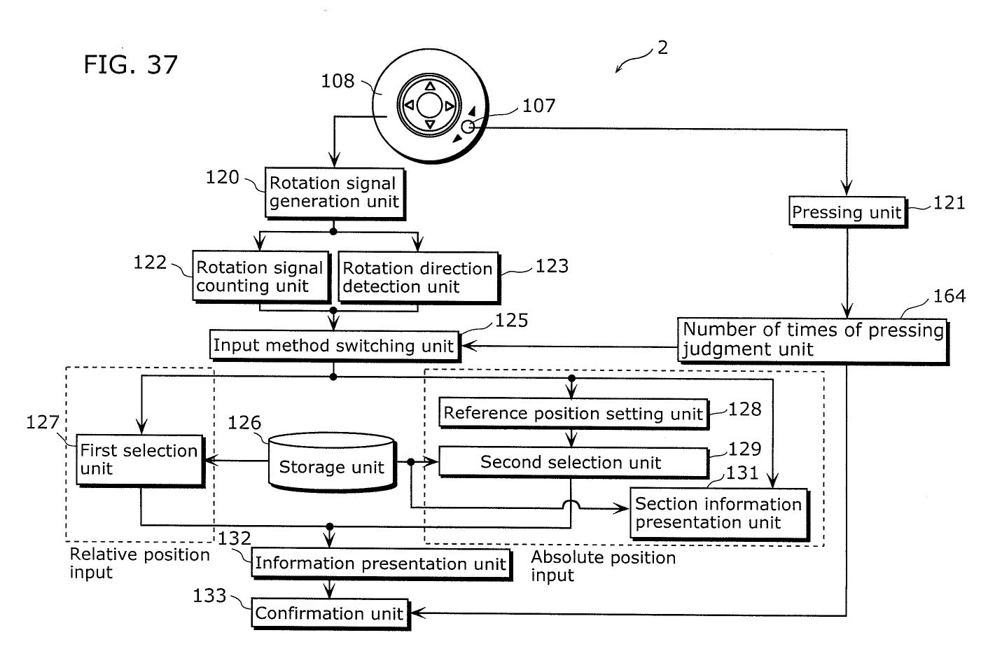

FIG. 37 is a block diagram showing the functional configuration of the input device 2 in the fourth embodiment of the present invention. This input device 2 functionally includes the rotation signal generation unit 120, the pressing unit 121, the rotation signal counting unit 122, the rotation direction detection unit 123, a number of times of pressing judgment unit 164, the input method switching unit 125, the storage unit 126, the first selection unit 127, the reference position setting unit 128, the second selection unit 129, the section information presentation unit 131, the information presentation unit 132, and the confirmation unit 133. In other words, this input device 2 is different from the above described third embodiment only in that the number of times of pressing judgment unit 164 has been included instead of the pressing time judgment unit 124.

The number of times of pressing judgment unit 164 is a pressing sensing unit according to the present invention, and senses whether or not the pressing unit 121 is being pressed. Specifically, the pressing signal of the pressing unit 121 and the energized terminal ID are outputted to either the input method switching unit 125 or the confirmation unit 133, by judging the number of times of pressing on the pressing unit 121 within a predetermined time. In other words, when the pressing unit 121 has been pressed once again without the wheel unit 108 being rotated, within the predetermined time after the pressing unit 121 has been depressed, the pressing signal and the energized terminal ID are outputted to the input method switching unit 125. On the other hand, when the pressing unit 121 has never been pressed within the predetermined time after the pressing unit 121 has been depressed, the pressing signal and the energized terminal ID are outputted to the confirmation unit 133. It is desirable that the number of times of pressing judgment unit 164 is composed of software.

Since other components are similar to the above described third embodiment, descriptions thereof are omitted.

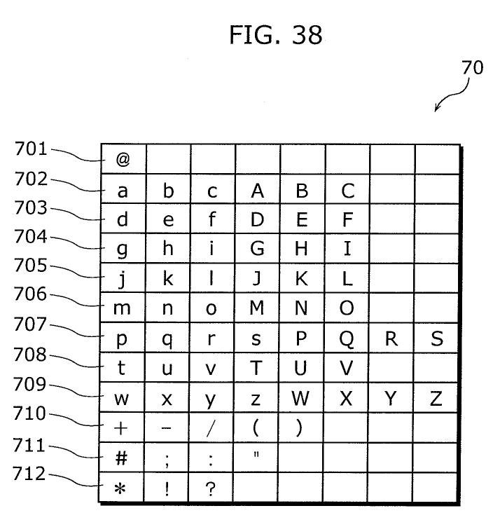

FIG. 38 is an example of character information 70 included in the storage unit 126 included in the input device 2 in the present embodiment. The character information 70 is composed of the alphabet and the signs, and is grouped into line information 701 to 712.

The information presentation unit 132 presents at least some of the line information 701 to 712, as the selected target information, to the user.

The first selection unit 127 or the second selection unit 129 selects predetermined line information from among the selected target information, based on the rotation angle and the rotation direction of the wheel unit 108. When confirmation of selection of a desired line from the user has been accepted (for example, when the depression of the wheel button 107 is accepted while “m” line 706 is being selected), the confirmation unit 133 confirms the selected line (“m” line), and the information presentation unit 132 presents at least some of character information set (in this case, “m”, “n”, “o”, “M”, “N”, and “O”) constituting the confirmed line, as the selected target information. Subsequently, when the user rotates the wheel unit 108, the physical amount related to this rotation is identified by the rotation signal counting unit 122 and the rotation direction detection unit 123. Thereby, depending on the physical amount related to this rotation, a desired character (for example, “M”) is selected by the first selection unit 127 or the second selection unit 129. When the wheel button 107 is further depressed in that state, the character being selected (“M”) is confirmed as the input character by the confirmation unit 133. It should be noted that, after this, the state becomes a state in which the line information can be selected again.

Here, a character information set representing the lines of the 50 syllables of the hiragana (“a”, “d”, “g”, “j”, “m”, and the like) corresponds to “first information set” of the present invention. Moreover, a character information set constituting the lines of the 50 syllables of the hiragana (for example, “a”, “b”, “c”, “A”, “B”, and “C” constituting “a” line, and “d”, “e”, “f”, “D”, “E”, and “F” constituting “d” line) corresponds to “second unit information” of the present invention.

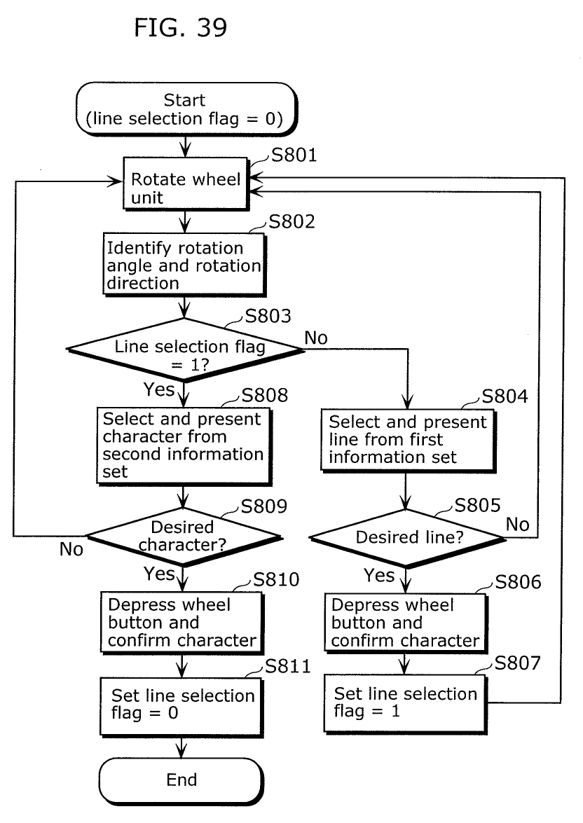

FIG. 39 is a flowchart showing a procedure when a character is inputted according to the relative position input method by using the mobile terminal 1 including the input device 2 in the present embodiment. Specifically, a series of flows until the first selection unit 127 selects desired unit information from among the selected target information presented by the information presentation unit 132, based on the rotation angle and the rotation direction of the wheel unit 108, and the confirmation unit 133 confirms the selection by detecting the depression of the wheel button 107 is shown.

First, since the wheel unit 108 is rotated by the user (S801), the wheel unit 108 outputs the rotation signal. The rotation signal counting unit 122 and the rotation direction detection unit 123 identify the rotation angle and the rotation direction of the wheel unit 108 from this rotation signal (S802). At this time, based on the rotation angle and the rotation direction of the wheel unit 108, when the line selection flag included within the input device 2 is “0” (S803: No), the first selection unit 127 selects predetermined character information from the first information set being selected by the information presentation unit 132 (S804), and when the line selection flag is “1” (S803: Yes), the first selection unit 127 selects predetermined character information from the second information set (S808).

When the user hopes to confirm the input for the desired information being selected by the first selection unit 127 and displayed in the fixed frame 41 (S805: Yes, or S809: Yes), the user depresses the wheel button 107, and when the user hopes to select another information, the user rotates the wheel unit 108 again (S805: No, or S809: No). With the depression of the wheel button 107, the confirmation unit 133 confirms the input of confirmation of the selected information (S806, S810). The input device 2 sets the line selection flag included therein to “1” when the selection of the predetermined information from among the first information set has been confirmed (S807), and sets the line selection flag to “0” when the selection of the predetermined information from among the second information set has been confirmed (S811). According to such a series of flows, the input of one character is confirmed. After the input of one character has been confirmed, when the wheel unit 108 has been further rotated by the user (S801), the line selection flag is set to “0”. Then, since at least some of the character information set representing the lines is being presented as the selected target information again by the information presentation unit 132, the first selection unit 127 selects the predetermined character information from among the above described character information representing the lines (S804).

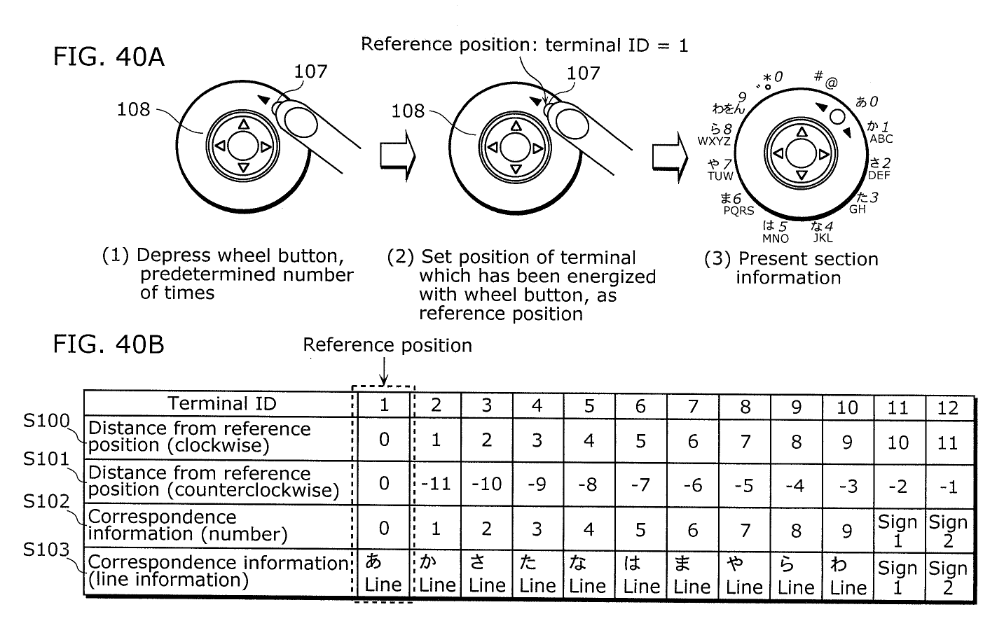

FIG. 40 is a diagram showing a procedure when the input method is switched from the relative position input to the absolute position input by using the input device 2 in the fourth embodiment of to the present invention. Specifically, FIG. 40A is a diagram showing the operational procedure until the section information is presented by the section information presentation unit 131, and FIG. 40B is a diagram showing the correspondence between the character-related information stored in the storage unit 126 and the sections.

When the number of times of pressing judgment unit 164 has sensed that the wheel button 107 has been pressed once again without the wheel unit 108 being rotated, within the predetermined time after the wheel button 107 has been depressed, the number of times of pressing judgment unit 164 outputs the terminal ID of the terminal 17 which has been energized with the wheel button 107, along with the depression signal, to the input method switching unit 125. Here, as shown in (1) and (2) of FIG. 40A, since a case where the wheel button 107 has been successively pressed twice at the position corresponding to the terminal 17(a) with the terminal ID of 1 is assumed, the terminal ID “1” is outputted from the number of times of pressing judgment unit 164 to the input method switching unit 125. At this time, when the relative position input method has been enabled, the input method switching unit 125 switches the input method to the absolute position input method. Thereby, the reference position setting unit 128 sets the position of the wheel button 107 at this time as the reference position by resetting the rotation angle and the rotation direction of the wheel unit 108 to 0. As a result, although the second selection unit 129 causes the character-related information to correspond to the sections, a method thereof is similar to the above described third embodiment. In other words, for the terminal 17(a) with the terminal ID of 1, as shown in S100 and S101 of FIG. 40B, the distance from the reference position becomes “0” which is the initial value, both when the wheel button 107 is clockwise and when the wheel button 107 is counterclockwise, and as shown in S102 of FIG. 40B, the correspondence information (number) becomes the number “0”, and as shown in S103 of FIG. 40B, the correspondence information (line information) becomes “ [symbol] (a)-line” of the hiragana. Then, as the terminal ID becomes larger like “2, 3, 4, . . . , 12”, the distance from the reference position (clockwise) becomes “1, 2, 3, . . . , 11”, the distance from the reference position (counterclockwise) becomes “−11, −10, −9, . . . , −1”, the correspondence information (number) becomes “1, 2, 3, . . . , sign 2”, and the correspondence information (line information) becomes “ [symbol] (ka)-line, [symbol] (sa)-line, [symbol] (ta)-line, sign 2”.

Moreover, as shown in (3) of FIG. 40A, similar to the above described third embodiment, the section information presentation unit 131 presents the section information which has been associated with each section by the second selection unit 129, around the wheel unit 108, by lighting the LED.

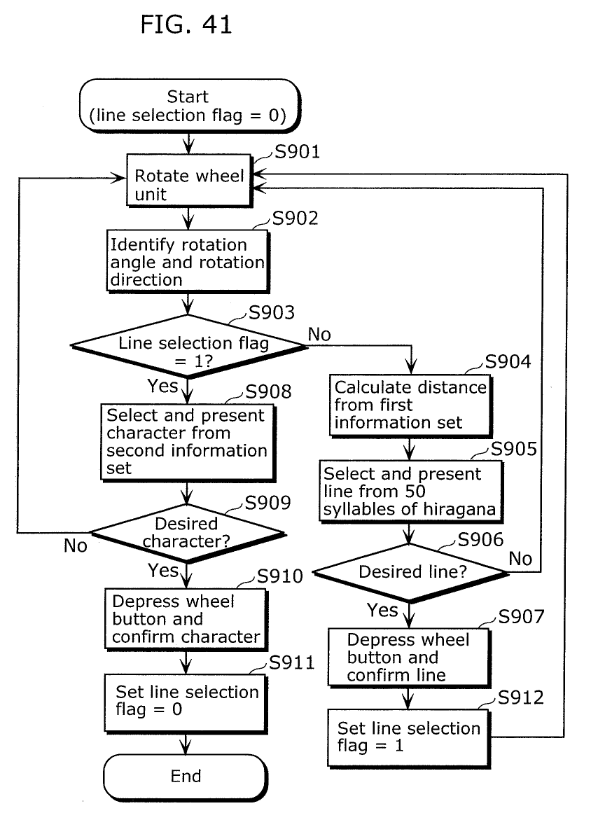

FIG. 41 is a flowchart showing a procedure for inputting a character according to the absolute position input method by using the mobile terminal 1 including the input device 2 in the fourth embodiment of the present invention. Here, a series of flows until the second selection unit 129 selects the information from the storage unit 126 based on the rotation angle and the rotation direction of the wheel unit 108, and the information confirmation unit 32 confirms the selection with the pressing on the wheel button 107 is described. It is assumed that the reference position has been already set according to the procedure described by using FIG. 40.

Since the user rotates the wheel unit 108 (S901), the wheel unit 108 outputs the rotation signal. The rotation signal counting unit 122 and the rotation direction detection unit 123 identify the rotation angle and the rotation direction of the wheel unit 108 from this rotation signal (S902). At this time, when the line selection flag which has been internally included in the input device 2 is 0 (S903: No), the second selection unit 129 calculates the distance from the reference position, based on the reference position set by the reference position setting unit 128, and the rotation angle and the rotation direction of the wheel unit 108 (S904). Subsequently, from among the character information 70, information corresponding to the distance from the reference position is selected (S905). On the other hand, when the line selection flag is 1 (S903: Yes), from among characters constituting the information being selected, a character corresponding to the rotation angle and the rotation direction of the wheel unit 108 is selected (S908).

When the desired information is being selected (S906: Yes, or S909: Yes), the user depresses the wheel button 107 and thereby confirms the selection of the information being selected (S907, S610). On the other hand, when the desired information is not being selected (S906: No, or S909: No), the wheel unit 108 is rotated again, and thereby another line information or character is selected (S901).

The input device 2 sets the line selection flag to 1 when the selection of the line information has been confirmed (S912), and sets the line selection flag to 0 when the selection of the character has been confirmed (S911). According to such a series of flows, the input of one character is confirmed. When the user has rotated the wheel unit 108 again for inputting, in continuation, another character (S901), since the line selection flag has been set to 0, it is possible to select the predetermined line information from among the character information 70 (S905).

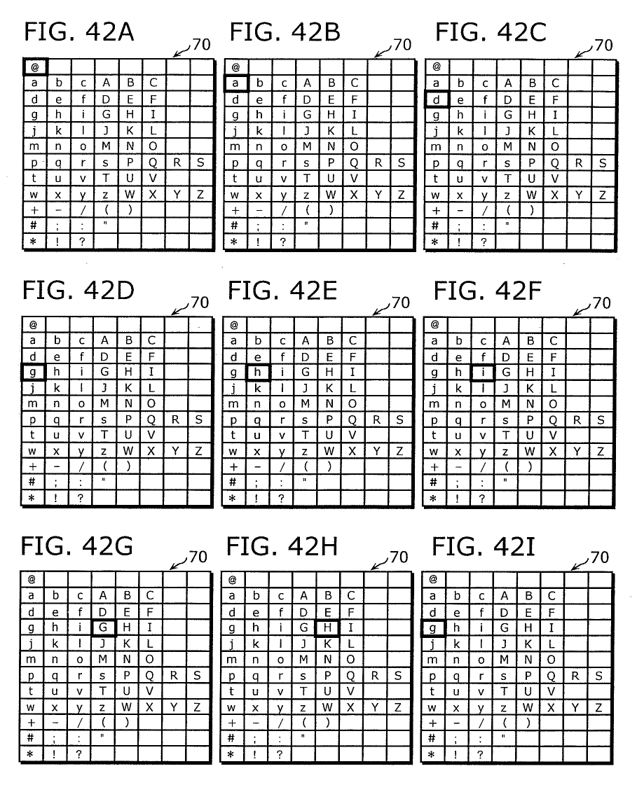

FIGS. 42A to 42I are diagrams showing a transition of a character which is selected from among the character information 70 when a character is inputted according to the relative position input method. Here, a case where a character “H” is inputted is illustrated and described.

First, as shown in FIG. 42A, when the user rotates the wheel unit 108 clockwise for three units in a state in which “@” line which is the first reference information has been selected, as shown in FIGS. 42B, 42C, and 42D, the lines are selected in an order of “a”, “d”, and “g”. When the user presses the wheel button 107 in a state in which “g” line has been selected in this way, the state becomes a state in which the respective characters “g”, “h”, “i”, “G”, “H”, and “I” constituting “g” line can be selected. As shown in FIGS. 42E, 42F, 42G, and 42H, when the user rotates the wheel unit 108 clockwise for four units in this state, the characters are selected in an order of “h”, “i”, “G”, and “H”. When the user presses the wheel button 107 in this state, the character “H” is confirmed as the input information.

Here, as shown in FIG. 42I, in the relative position input method, the first unit information “g” line which has been associated with “H” which is the second information set is selected, and subsequently, the information is selected from among the character information 70 in the same manner. In other words, when the input information is confirmed, “g” line which is the first reference information becomes the reference point, and when the wheel unit 108 rotates again, the rank moves depending on the amount of rotation.

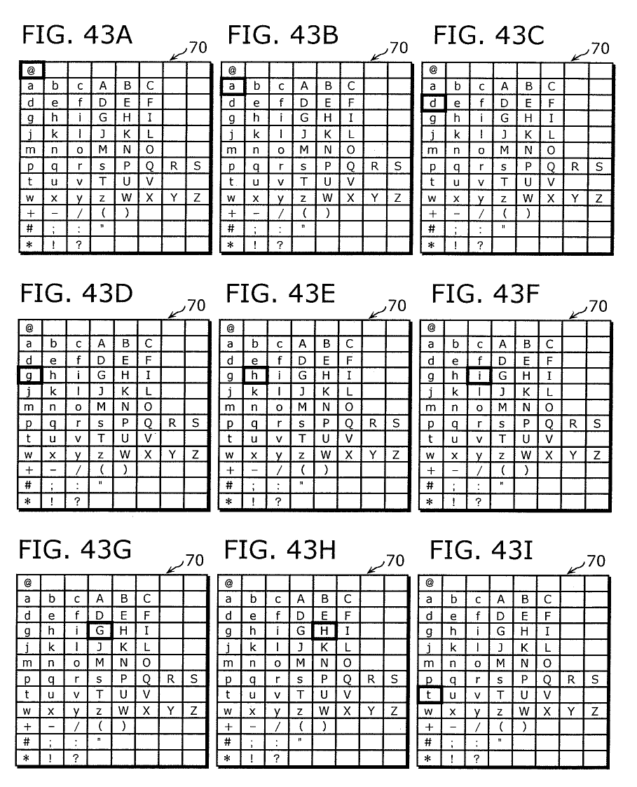

FIGS. 43A to 43I are diagrams showing a transition of a character which is selected from among the character information 70 when a character is inputted according to the absolute position input method. Also here, the case where the character “H” is inputted is illustrated and described.

The case is similar to the case of the relative position input method, until the character “H” is confirmed as the input information. In other words, as shown in FIG. 43A, when the user rotates the wheel unit 108 clockwise for three units in a state in which “@” line which is the second reference information has been selected, as shown in FIGS. 43B, 43C, and 43D, the lines are selected in the order of “a”, “d”, and “g”. When the user presses the wheel button 107 in the state in which “g” line has been selected in this way, the state becomes the state in which the respective characters “g”, “h”, “i”, “G”, “H”, and “I” constituting “g” line can be selected. As shown in FIGS. 43E, 43F, 43G, and 43H, when the user rotates the wheel unit 108 clockwise for four units in this state, the characters are selected in the order of “h”, “i”, “G”, and “H”. When the user presses the wheel button 107 in this state, the character “H” is confirmed as the input information.

Here, as shown in FIG. 43I, in the absolute position input method, “t” line is selected, and subsequently, the information is selected from among the character information 70 in the same manner. In other words, when the character “H” is confirmed as the input information, since the wheel unit 108 at the time has rotated clockwise for seven units from the reference position, “t” line to which the rank has moved for seven units from “@” line which is the second reference information is selected.

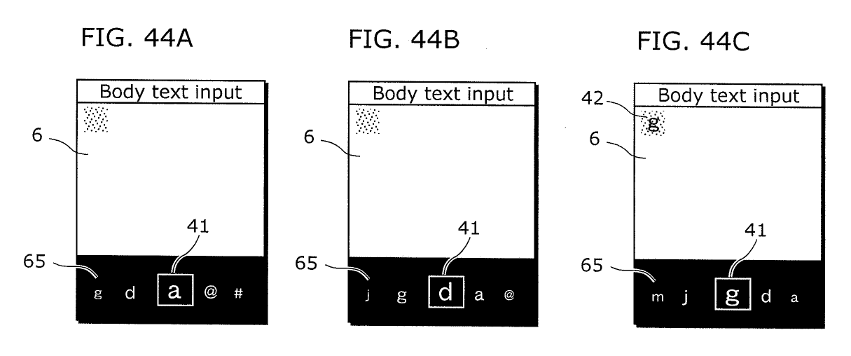

FIGS. 44A to 44C are diagrams showing an example of the information which is displayed on the display unit 6 when the input operation is performed by using the mobile terminal 1 including the input device 2 in the present embodiment, and mainly show changes in content to be presented on the information presentation unit 132 along with the input operation.

When the user performs the input operation, in selected target characters being presented on the display unit 6 by the information presentation unit 132, the predetermined character being selected by the first selection unit 127 or the second selection unit 129 (also referred to as “selected character”) is highlighted within the frame of the fixed frame 41, and is displayed in the font larger than other characters.

Moreover, the information presentation unit 132 presents a generally square-shaped wheel GUI 65, and arranges and displays the selected character and the character information adjacent thereto linearly in the wheel GUI 65. Since the selected character is highlighted and displayed in the font larger than the adjacent character information in this way, the user can clearly comprehend which character is the selected character. Moreover, since the selected character is displayed at the fixed position, the movement of the line of sight of the user during the operation is decreased, and it becomes further easy to comprehend the selected character. Furthermore, since not only the selected character but also the characters next thereto are displayed, the user can also check the characters previous and next to the selected character. Moreover, the wheel GUI 65 displays only some of the character information 70 stored in the storage unit 126. Since the information to be displayed is reduced in this way, it is possible to make it easier for the user to identify the character to be selected. For other character information 70 which is not being displayed, along with the rotation of the wheel unit 108, the information presentation unit 132 interchanges the selected target information being displayed so that all information can be selected.

Hereinafter, an operation when “c” of the alphabet is inputted is described by using FIGS. 44A to 44C. In FIG. 44A, in the characters constituting the first information set, “a” is being displayed in the fixed frame 41 on the wheel GUI 65. At this time, as shown in FIGS. 44B and 44C, when the user rotates the wheel unit 108 clockwise, depending on the rotation angle and the rotation direction, “d” and “g” are sequentially highlighted and displayed in order in the fixed frame 41 in the center. When the user depresses the wheel button 107 while “g” is being selected, the confirmation unit 133 confirms the selection of “g”, and displays “c” on the input screen 42.

According to the above operation, the user can easily input the desired character while seeing the display unit 6, without feeling the operational burden.

As described above, according to the mobile terminal 1 including the input device 2 in the present embodiment, it is possible to switch between the relative position input method suitable for inputting the information while seeing the display unit 6, and the absolute position input method suitable for inputting the information without seeing the display unit 6, by a simple operation of double-clicking on the wheel button 107. Thereby, it becomes possible to provide the input device with good operability, which can flexibly respond to the status in which the user is using the input device or the user's preferences.

It should be noted that, in the present embodiment, although it has been assumed that the number of times of pressing judgment unit 164 outputs the pressing signal to the input method switching unit 125 when the pressing unit 121 has been depressed, a predetermined number of times within the predetermined time, the above described predetermined time or the predetermined number of times may be any time and any number of times in which the user can clearly distinguish the normal pressing from the pressing for switching the input method.

Furthermore, in the present embodiment, although it has been assumed that when the number of times of pressing judgment unit 164 judges that the wheel button 107 has been double-clicked, the input method switching unit 125 performs the switching between the relative input method and the absolute input method, it may be assumed that the input method is switched with double-clicking on another button other than the double-clicking on the wheel button 107. Specifically, the input method may be switched by using the button of other than the wheel unit 108 included in the mobile terminal 1. In this case, it may be judged whether or not the button which is used for the above described switching is being depressed.

Moreover, according to the mobile terminal 1 including the input device 2 according to the present embodiment, at the time of the relative position input method, when the selection of the first information set is selected, in continuation, after the selection of the predetermined information in the second information set has been confirmed, the first unit information which has been associated with the above described selected second information set is selected.

With the above described effects, according to the input device 2 according to the present embodiment, the burden on the user's hand or finger is reduced and the time required for the operation is also reduced, which enables the comfortable operation.

### FIFTH EMBODIMENT

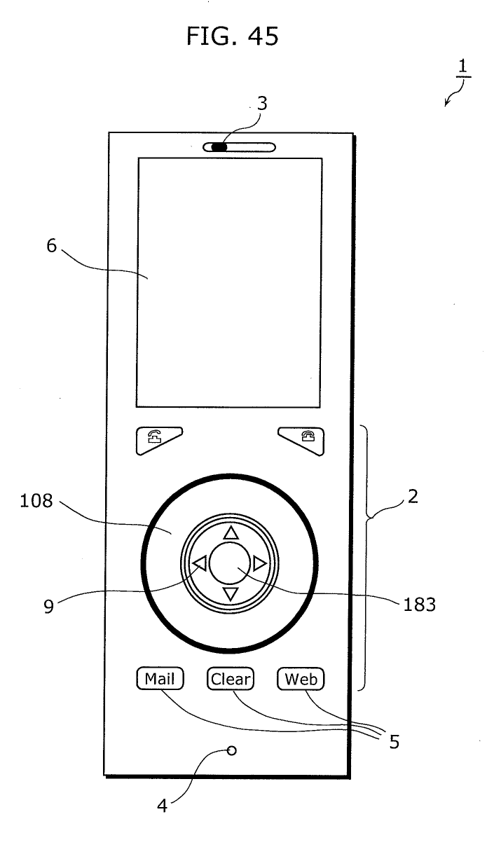

The present embodiment is described with a focus on different points from the above described third embodiment and fourth embodiment, by using FIGS. 45 to 49. It should be noted that the same reference characters are used for components similar to the above described third embodiment, and descriptions thereof are omitted.

FIG. 45 is an external view of the mobile terminal 1 including the input device 2 in the present embodiment. This mobile terminal 1 includes an integrated antenna, has the functions which realize the telephone calls, the transmission and the receiving of the mails, the Internet connections, and the like, and can communicate with another terminal or the base station. Moreover, when the mail function, the Internet browsing function, and other functions are used, it is possible to input the characters by using the input device 2.

The input device 2 included in the mobile terminal 1 is composed of the function invocation keys 5 for invoking the functions (for example, the mail function, the telephone call function, the Web function, the clear function, and the like) included in the mobile terminal 1, the wheel unit 108 which is freely rotatable within the plane in parallel with the housing of the mobile terminal 1 and composed of the rotary encoder of the photoelectric method, a depressible wheel button 183 included at a rotation center of the wheel unit 108, and the direction key 9 which selects the desired function or character from the plurality of the functions or the characters. The user can invoke the desired function or input the characters by using this input device 2.

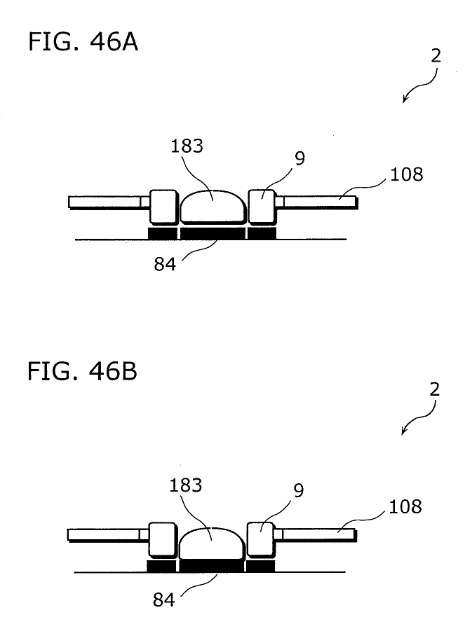

FIGS. 46A and 46B are cross-sectional diagrams showing the structure of the input device 2 in the present embodiment, and are diagrams schematically representing conditions before the wheel button 183 is depressed (FIG. 46A) and after the wheel button 183 is depressed (FIG. 46B). The input device 2 is a so-called push switch, and is energized with a terminal 84 when being depressed. The input device 2 detects the energization with the terminal 84 when the wheel button 183 has been depressed, as the depression signal. In this way, the input device 2 may have any mechanism in which both the signal depending on the rotation of the wheel unit 108 and the signal depending on the depression of the wheel button 183 can be outputted, and may also be realized with other structures.

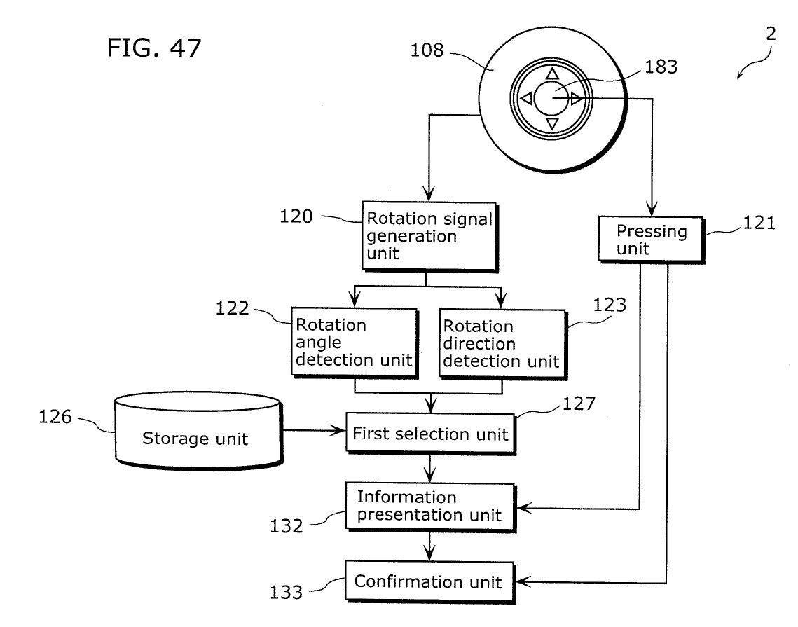

FIG. 47 is a block diagram showing the functional configuration of the input device 2 in the present embodiment. This input device 2 functionally includes the rotation signal generation unit 120, the pressing unit 121, the rotation signal counting unit 122, the rotation direction detection unit 123, the input method switching unit 125, the storage unit 126, the first selection unit 127, the information presentation unit 132, and the confirmation unit 133. In other words, this input device 2 is different from the above described third embodiment and fourth embodiment in that the pressing unit 121 has not been arranged on the wheel unit 108. Since other components are similar to the above described third embodiment and fourth embodiment, descriptions thereof are omitted.

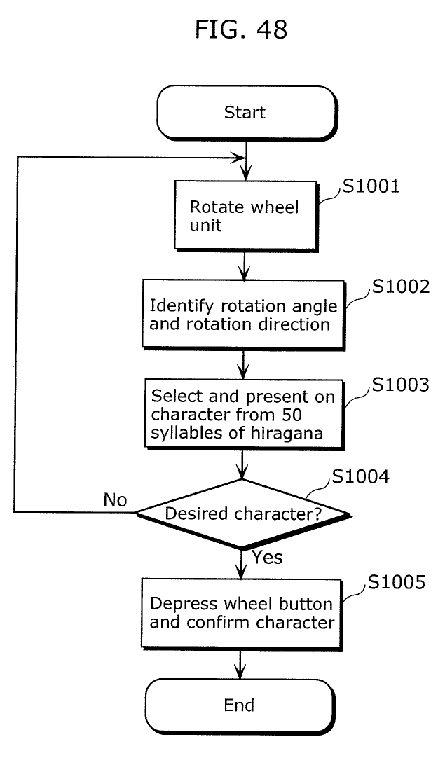

FIG. 48 is a flowchart showing a procedure when a character is inputted by using the mobile terminal 1 including the input device 2 in the present embodiment. Specifically, a series of processing flows until the first selection unit 127 selects desired unit information from among the selected target information presented on the display unit 6 by the information presentation unit 132, based on the rotation angle and the rotation direction of the wheel unit 108, and the confirmation unit 133 confirms the selection with the depression of the wheel button 183 is shown.

First, since the wheel unit 108 is rotated by the user (S1001), the wheel unit 108 outputs the rotation signal. The rotation signal counting unit 122 and the rotation direction detection unit 123 identify the rotation angle and the rotation direction of the wheel unit 108 from this rotation signal (S1002). At this time, when the user hopes to confirm the input for the desired character being selected by the selection unit 25 and displayed in the fixed frame 41 (S1004: Yes), the user depresses the wheel button 63, and when the user hopes to select another character, the user rotates the wheel unit 108 again (S1004: No). The confirmation unit 133 confirms the input of the character information representing the selected character with the depression of the wheel button 183 (S1005). According to such a series of flows, the input of one character is confirmed. When the user has rotated the wheel unit 108 again for inputting, in continuation, another character (S1001), it is possible to select and confirm the predetermined character from among the characters being presented by the information presentation unit 132 (S1005).

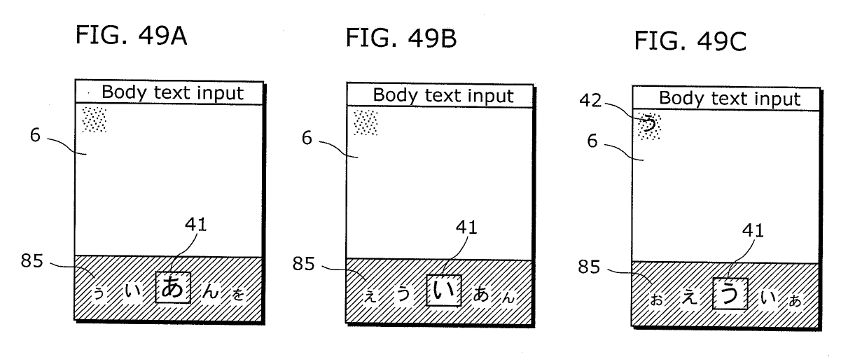

FIGS. 49A to 49C are diagrams showing an example of the information which is displayed on the display unit 6 when the input operation is performed by using the mobile terminal 1 including the input device 2 in the present embodiment, and mainly show changes in the content to be presented on the information presentation unit 132 along with the input operation.

When the user performs the input operation, in the selected target characters being presented on the display unit 6 by the information presentation unit 132, the predetermined character being selected by the first selection unit 127 (also referred to as “selected character”) is highlighted within the frame of the fixed frame 41, and is displayed in the font larger than other characters. Moreover, the information presentation unit 132 presents a generally square-shaped wheel GUI 85, and arranges and displays the selected character and the character information adjacent thereto linearly in the wheel GUI 85. Since the selected character is highlighted and displayed in the font larger than the adjacent character information in this way, the user can clearly comprehend which character is the selected character.

Hereinafter, an operation when “ [symbol] (u)” of the hiragana is inputted is described by using FIGS. 49A to 49C. In FIG. 49A, in the character information, the beginning character “ [symbol] (a)” is being displayed in the fixed frame 41 on the wheel GUI 85. At this time, as shown in FIGS. 49B and 49C, when the user rotates the wheel unit 108 clockwise, depending on the rotation angle and the rotation direction, “ [symbol] (i)” and “ [symbol] (u)” are sequentially highlighted and displayed in order in the fixed frame 41 in the center. When the user depresses the wheel button 183 while “ [symbol] (u)” is being selected, the confirmation unit 133 confirms the selection of “ [symbol] (u)”, and displays “ [symbol] (u)” on the input screen 42.

As described above, according to the mobile terminal 1 including the input device 2 in the present embodiment, since the wheel button 183 is provided at the rotation center of the wheel unit 108, when the user performs the input operation, the user can easily operate the wheel button 183 with the finger at any position on the wheel unit 108, and it is possible to reduce a burden associated with the movement of the finger and reduce a time required for the movement of the finger. Thereby, it becomes possible for the user to easily input the desired character while seeing the display unit 6, without feeling the operational burden.

### INDUSTRIAL APPLICABILITY

The input device according to the present invention is applicable to a mobile phone, a mobile-type music terminal, a remote controller of a television, a gaming machine, and the like in which the user needs to efficiently find the target information.

1. An input device which inputs information, said device comprising:
an operation unit which is operated by a user;
a movement sensing unit configured to sense a physical amount related to a movement of an object in contact with a surface of said operation unit, or a physical amount related to a movement of said operation unit;
a pressing sensing unit configured to sense that the surface of said operation unit is pressed;
an information set storage unit configured to store a plurality of information sets constituting a hierarchical structure with at least three layers;
a selection unit configured to select unit information from among the information sets, depending on the physical amount which is sensed by said movement sensing unit; and
a confirmation unit configured to confirm the selection of the unit information, when it is sensed by said pressing sensing unit that said operation unit is pressed or that the pressing on said operation unit is released,
wherein when the selection of unit information in an information set of an n-th layer is confirmed by said confirmation unit, said selection unit is configured to shift to a state in which unit information is selected from among an information set of an m-th layer between a highest layer and the n-th layer.

2. The input device according to claim 1,
wherein the information set belonging to the m-th layer is a collection of line information corresponding to each character constituting a beginning line of a 50-character hiragana syllabary, and the information set belonging to the n-th layer is a collection of column information corresponding to each character belonging to each line of the 50-character hiragana syllabary.

3. The input device according to claim 1,
wherein the information set belonging to the m-th layer is a collection of unit information indicating an artist, and the information set belonging to the n-th layer is a collection of unit information indicating a tune belonging to the artist.

4. The input device according to claim 1,
wherein the information set belonging to the m-th layer is a collection of unit information indicating a music album, and the information set belonging to the n-th layer is a collection of unit information indicating a tune belonging to the music album.

5. The input device according to claim 1,
wherein the information set belonging to the m-th layer is a collection of unit information indicating a music genre, and the information set belonging to the n-th layer is a collection of unit information indicating a tune constituting the music genre.

6. The input device according to claim 1,
wherein the information set belonging to the m-th layer is a collection of unit information indicating a music playlist, and the information set belonging to the n-th layer is a collection of unit information indicating a tune belonging to the music playlist.

7. The input device according to claim 1,
wherein the information set belonging to the m-th layer is a collection of unit information indicating a television program genre, and the information set belonging to the n-th layer is a collection of unit information indicating a television program belonging to the television program genre.

8. The input device according to claim 1,
wherein said information set storage unit is configured to store a first information set which is a collection of first unit information, and a second information set which is a collection of second unit information associated with the first unit information, and
when the second unit information is confirmed as input information by said confirmation unit, said selection unit is configured to return to selection of the first unit information from the first information set.

9. The input device according to claim 8,
wherein said selection unit is configured to start the selection of the first unit information, with the first unit information associated with the second information set, as a reference point.

10. The input device according to claim 8, comprising
an information presentation unit configured to present, on a screen, selected target information selected by said selection unit, said selected target information including at least a portion of the information sets,
wherein, when the second unit information is confirmed as the input information by said confirmation unit, said information presentation unit is configured to present, on the screen, an information set including the first unit information associated with the second information set, as the selected target information.

11. The input device according to claim 10,
wherein, when presenting the first unit information as the selected target information, said information presentation unit is configured to present the first unit information in an external appearance different from other unit information in the selected target information.

12. The input device according to claim 11,
wherein said information presentation unit is configured to present the first unit information selected by said selection unit, in a display size larger than selected target unit information other than the first unit information.

13. The input device according to claim 11,
wherein said information presentation unit is configured to present a predetermined piece of the first unit information selected by said selection unit, in a color different from the selected target information other than the first unit information.

14. The input device according to claim 1, comprising
a history information retention unit configured to store history information related to unit information confirmed in the past, as input information, by said confirmation unit,
wherein said selection unit is configured to select the unit information which becomes a reference point, based on the history information.

15. The input device according to claim 1,
wherein said operation unit is a rotary body provided on a base body of said input device,
said movement sensing unit is an amount of rotation sensing unit configured to sense an amount of rotation of said rotary body,
said selection unit includes: a first selection unit configured to select information from among the information sets, depending on the amount of rotation from a position of said rotary body when said rotary body is pressed and immediately preceding input information is confirmed, with first reference unit information in the information sets as a reference point; and a second selection unit configured to select unit information from among the information sets, depending on the amount of rotation from a reference position of said rotary body, with second reference unit information in the information sets as the reference point, and
said input device further comprises a switching unit configured to switch between said first selection unit and said second selection unit.

16. The input device according to claim 15, further comprising
a reference position setting unit configured to change the amount of rotation to 0 when the switching from said first selection unit to said second selection unit is performed by said switching unit, and thereby set, as the reference position, a position of said rotary body at a time point when the switching is performed.

17. The input device according to claim 15,
wherein, when it is sensed by said pressing sensing unit that a duration in which said rotary body is pressed is equal to or more than a predetermined threshold, said switching unit is configured to switch between said first selection unit and said second selection unit.

18. The input device according to claim 15,
wherein, when it is sensed by said pressing sensing unit that the number of times that said rotary body is successively pressed is equal to or more than a predetermined threshold, said switching unit is configured to switch between said first selection unit and said second selection unit.

19. The input device according to claim 15,
wherein said pressing sensing unit is configured to sense whether or not there is pressing on a predetermined button; and
when it is sensed by said pressing sensing unit that a duration for which the predetermined button is pressed is equal to or more than a predetermined threshold, said switching unit is configured to switch between said first selection unit and said second selection unit.

20. The input device according to claim 15,
wherein said pressing sensing unit is configured to sense whether or not there is pressing on a predetermined button; and
when it is sensed by said pressing sensing unit that the number of times the predetermined button is successively pressed is equal to or more than a predetermined threshold, said switching unit is configured to switch between said first selection unit and said second selection unit.

21. The input device according to claim 15, further comprising
a switch,
wherein, when said switch is switched, said switching unit is configured to switch between said first selection unit and said second selection unit.

22. The input device according to claim 15, further comprising
an information presentation unit configured to present, at a periphery of said rotary body, an information set including information which is selected by said second selection unit.

23. The input device according to claim 15,
wherein, when said second reference unit information is a number “0” and said rotary body is at the reference position, said second selection unit is configured to select “0” as input information.

24. The input device according to claim 15,
wherein, when said second reference unit information is “a” of alphabet and said rotary body is at the reference position, said second selection unit is configured to select “a” of the alphabet as input information.

25. A mobile terminal comprising said input device according to claim 1.

26. An input method for inputting unit information from among a plurality of information sets constituting a hierarchical structure with at least three layers, using an input device including an operation unit which is operated by a user, based on an operation of the operation unit, said method comprising:
sensing a physical amount related to a movement of an object in contact with a surface of the operation unit, or a physical amount related to a movement of the operation unit;
sensing that the operation unit is pressed;
selecting unit information from among the information sets, depending on the physical amount which is sensed in said sensing that the operation unit is pressed; and
confirming the selection of the unit information, when it is sensed, in said sensing that the rotary body is pressed, that the operation unit is pressed or that the pressing on the operation unit is released,
wherein, when selection of unit information in an information set of an n-th layer is confirmed in said confirming, said selecting shifts to a state in which unit information is selected from among an information set of an m-th layer between a highest layer and the n-th layer.

27. A program for inputting unit information from among a plurality of information sets constituting a hierarchical structure with at least three layers, using an input device including an operation unit which is operated by a user, based on an operation of the operation unit, said program causing the input device to execute:
sensing a physical amount related to a movement of an object in contact with a surface of the operation unit, or a physical amount related to a movement of the operation unit;
sensing that the operation unit is pressed;
selecting unit information from among the information sets, depending on the physical amount which is sensed in said sensing that the operation unit is pressed; and
confirming the selection of the unit information, when it is sensed, in said sensing that the rotary body is pressed, that the operation unit is pressed or that the pressing on the operation unit is released,
wherein, when selection of unit information in an information set of an n-th layer is confirmed in said confirming, said selecting shifts to a state in which unit information is selected from among an information set of an m-th layer between a highest layer and the n-th layer.
